(19) United States
(12) Patent Application Publication
(10) Pub. No.: US 2026/0164773 A1
(43) Pub. Date: Jun. 11, 2026

(54) SEMICONDUCTOR DEVICE HAVING FRONTSIDE AND BACKSIDE CONTACTS

(71) Applicant: SAMSUNG ELECTRONICS CO., LTD., SUWON-SI (KR)

(72) Inventors: Sungwan LIM, Suwon-si (KR); Heonjong SHIN, Suwon-si (KR); Seowoo NAM, Suwon-si (KR); June Young PARK, Suwon-si (KR); Sunggyu HAN, Suwon-si (KR)

(21) Appl. No.: 19/181,458

(22) Filed: Apr. 17, 2025

(30) Foreign Application Priority Data
Sep. 13, 2024 (KR) 10-2024-0125893

(51) Int. Cl. H10D 84/83; H10D 30/00; H10D 30/01; H10D 30/43; H10D 62/10; H10D 62/13; H10D 64/23; H10D 84/01; H10W 20/41; H10W 20/42

(52) U.S. Cl. CPC H10D 84/8312; H10D 30/43; H10D 30/502; H10D 62/121; H10D 62/151; H10D 64/256; H10D 84/83125; H10D 84/832; H10W 20/422; H10W 20/435; H10D 30/014; H10D 30/0191; H10D 84/0133; H10D 84/0149

(57) ABSTRACT

A semiconductor device includes a base pattern and a first active pattern disposed on a frontside of the base pattern. A second active pattern is spaced apart from the first active pattern and is disposed on the frontside of the base pattern. A first source/drain pattern is connected to the first active pattern on the frontside of the base pattern. A second source/drain pattern is spaced apart from the first source/drain pattern and is connected to the second active pattern on the frontside of the base pattern. A first backside source/drain contact is connected to the first source/drain pattern from a backside of the base pattern. A backside wiring pattern is connected to the first backside source/drain contact. A backside connection via is disposed between the first source/drain pattern and the second source/drain pattern and is connected to the backside wiring pattern.

### CROSS-REFERENCE TO RELATED APPLICATIONS

This application claims priority under 37 C.F.R. § 119 to Korean Patent Application No. 10-2024-0125893, filed on Sep. 13, 2024, in the Korean Intellectual Property Office, the disclosure of which is herein incorporated by reference in its entirety.

### TECHNICAL FIELD

The present disclosure relates to a semiconductor device and, more specifically, to a semiconductor device having frontside and backside contacts.

### DISCUSSION OF THE RELATED ART

A multi-gate transistor has been proposed as a scaling technology to increase the density of semiconductor devices. In this design, a multichannel active pattern shaped like a fin or a nanowire is formed on a substrate, with a gate positioned on the surface of the active pattern.

In semiconductor devices, such as logic circuits, various source and drain regions are connected to metal wiring in the back-end-of-line (BEOL) through contact structures. There is a need for a method that allows some wiring (e.g., power lines) to be placed in the BEOL on the backside of the substrate, along with the formation of conductive structures that penetrates the substrate to establish connections with this wiring.

### SUMMARY

A semiconductor device includes a base pattern. A first active pattern is disposed on a frontside of the base pattern. The first active pattern is spaced apart from the base pattern in a first direction. A second active pattern is disposed on the frontside of the base pattern. The second active pattern is spaced apart from the base pattern in the first direction and is spaced apart from the first active pattern in a second direction crossing the first direction. A first source/drain pattern is connected to the first active pattern on the frontside of the base pattern. A second source/drain pattern is spaced apart from the first source/drain pattern in the second direction and is connected to the second active pattern on the frontside of the base pattern. A first backside source/drain contact is connected to the first source/drain pattern from a backside of the base pattern disposed opposite to the frontside of the base pattern. A backside wiring pattern is disposed on the backside of the base pattern and extends from the backside of the base pattern in a third direction crossing the first direction. The backside wiring pattern is connected to the first backside source/drain contact. A backside connection via is disposed between the first source/drain pattern and the second source/drain pattern and extends in the first direction and is connected to the backside wiring pattern.

A semiconductor device includes a first active pattern including a plurality of first nano-sheets spaced apart from one another in a first direction. A second active pattern is spaced apart from the first active pattern in a second direction crossing the first direction and the second active pattern includes a plurality of second nano-sheets that are spaced apart from one another in the first direction. A first source/drain pattern is connected to the first active pattern in a third direction crossing the first direction and the second direction. A second source/drain pattern is connected to the second active pattern in the third direction crossing the first direction and the second direction. A first frontside source/drain contact is disposed on the first source/drain pattern. A first backside source/drain contact is disposed below the first source/drain pattern. A backside connection via is disposed between the first source/drain pattern and the second source/drain pattern, extends in the first direction, and is connected to the first frontside source/drain contact.

A semiconductor device includes a first active pattern including a plurality of first nano-sheets that are spaced apart from one another in a first direction. A second active pattern is spaced apart from the first active pattern in a second direction crossing the first direction and includes a plurality of second nano-sheets that are spaced apart from one another in the first direction. A first source/drain pattern is connected to the first active pattern in a third direction crossing the first direction and the second direction. A second source/drain pattern is connected to the second active pattern in the third direction crossing the first direction and the second direction. A first frontside source/drain contact is disposed on the first source/drain pattern and the second source/drain pattern. A first backside source/drain contact is disposed below the first source/drain pattern. A second backside source/drain contact is disposed below the second source/drain pattern. A backside connection via is disposed between the first source/drain pattern and the second source/drain pattern, extends in the first direction, and is connected to the first frontside source/drain contact. A backside wiring pattern is disposed below the first source/drain pattern and the second source/drain pattern in the third direction and is connected to the first backside source/drain contact, the second backside source/drain contact, and the backside connection via.

### BRIEF DESCRIPTION OF THE FIGURES

These and/or other aspects and features of the invention will become apparent and more readily appreciated from the following description of example embodiments, taken in conjunction with the accompanying drawings of which:

FIG. 1 is a layout diagram illustrating a semiconductor device according to example embodiments;

FIG. 2 is a cross sectional view taken along line A-A of FIG. 1;

FIG. 3 is a cross sectional view taken along line B-B of FIG. 1;

FIG. 4 is a cross sectional view taken along line C-C of FIG. 1;

FIG. 5 is a cross sectional view taken along line D-D of FIG. 1;

FIG. 6 is a cross sectional view illustrating a semiconductor package according to example embodiments;

FIG. 7 is a cross sectional view taken along line C-C of FIG. 1 according to example embodiments;

FIG. 8 is a cross sectional view taken along line C-C of FIG. 1 according to example embodiments;

FIG. 9 is a cross sectional view taken along line C-C of FIG. 1 according to example embodiments;

FIG. 10 is a cross sectional view taken along line C-C of FIG. 1 according to example embodiments;

FIG. 11 is a cross sectional view taken along line C-C of FIG. 1 according to example embodiments; and

FIGS. 12 through 29 are cross sectional views illustrating intermediate operations of a method of manufacturing a semiconductor device according to example embodiments.

### DETAILED DESCRIPTION

In describing embodiments of the present disclosure illustrated in the drawings, specific terminology is employed for sake of clarity. However, the present disclosure is not necessarily intended to be limited to the specific terminology so selected, and it is to be understood that each specific element includes all technical equivalents which operate in a similar manner.

In the following descriptions, terms in a singular form may include terms in a plural form unless an apparently and contextually conflicting description is present. Terms such as “including” or “comprising” indicate that a feature, a number, an operation, an action, an element, a component, or a combination thereof is present. It should be understood that the terms do not necessarily exclude a possibility that one or more other features, numbers, operations, actions, elements, components, or combinations thereof may be present or added.

Expressions such as an upper side, an upper portion, a lower side, a lower portion, a side surface, a front surface, or a rear surface is based on directions illustrated in the drawings and that the expression may be changed when a direction of a corresponding object is changed. To the extent that an element is not described in detail with respect to this figure, it may be understood that the element is at least similar to a corresponding element that has been described elsewhere within the present disclosure

The drawings for a semiconductor device, according to example embodiments, illustrate a fin field-effect transistor (FinFET) including a channel area having a fin-shaped pattern shape, a transistor including a nanowire or a nano-sheet, and a multi-bridge channel field effect transistor (MBCFETTM) as examples, but it is an example and other structures may be used within the spirit and scope of the present disclosure.

The semiconductor device, according to example embodiments, may include a tunneling field-effect transistor (tunneling FET), a three-dimensional (3D) transistor, or a vertical field-effect transistor (vertical FET). The semiconductor device, according to example embodiments, may also include a planar transistor. In addition, the technical idea of the present disclosure may be applied to two-dimensional material-based field-effect transistors (2D material based FETs) and a heterostructure thereof. Also, the semiconductor device, according to example embodiments, may include a bipolar junction transistor, a lateral double-diffused transistor (e.g., laterally-diffused metal-oxide semiconductor (LDMOS)), or the like.

Hereinafter, example embodiments of the present disclosure will be described with reference to the drawings.

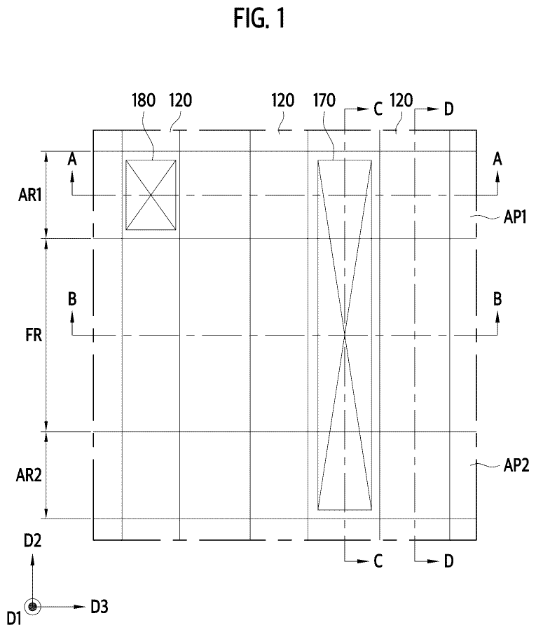

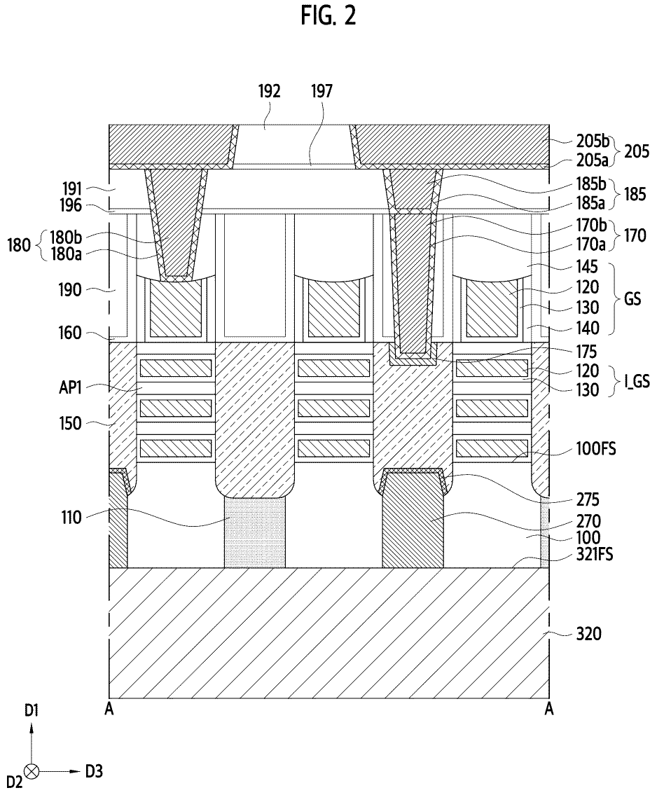

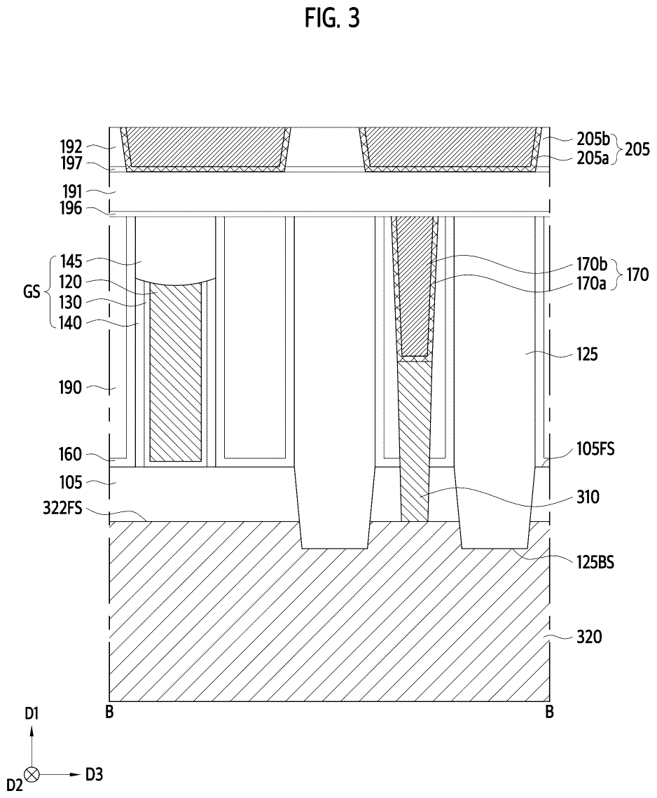

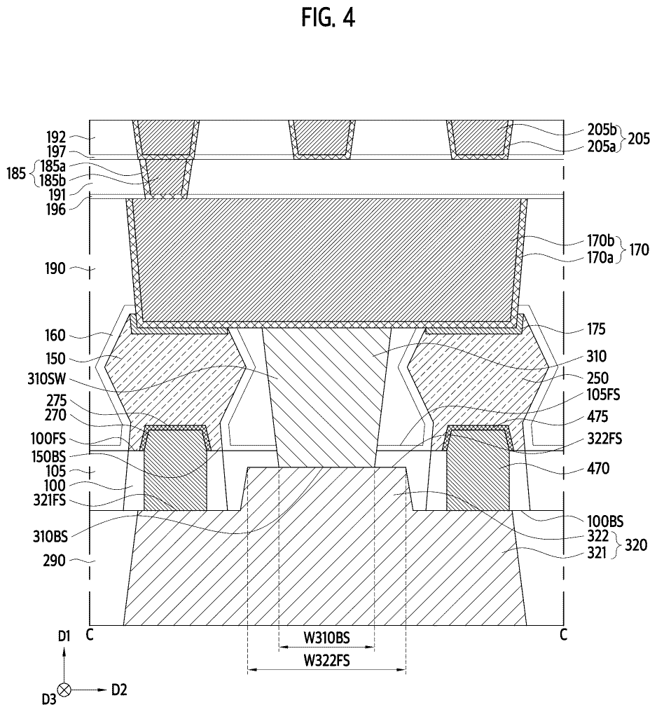

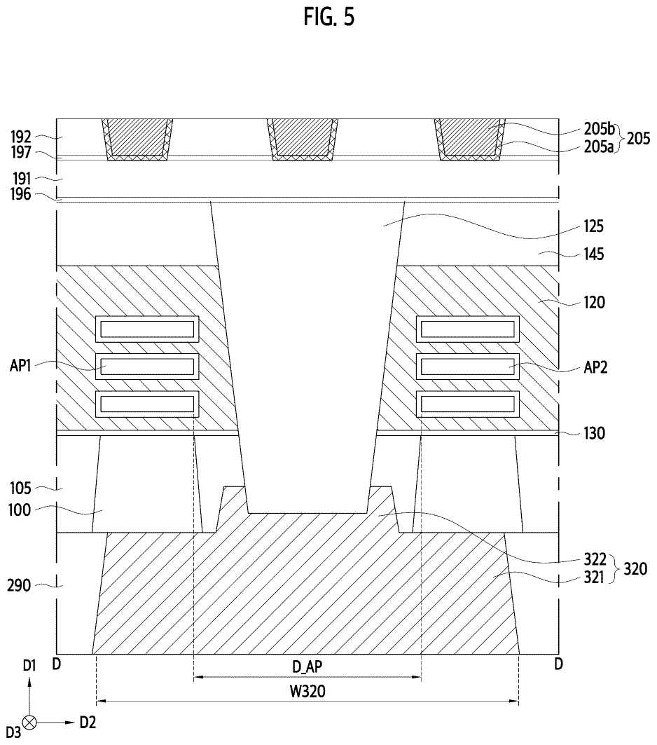

FIG. 1 is a layout diagram illustrating a semiconductor device according to example embodiments. FIG. 2 is a cross sectional view taken along line A-A of FIG. 1. FIG. 3 is a cross sectional view taken along line B-B of FIG. 1. FIG. 4 is a cross sectional view taken along line C-C of FIG. 1. FIG. 5 is a cross sectional view taken along line D-D of FIG. 1.

Referring to FIGS. 1 through 5, the semiconductor device, according to example embodiments, may include a base pattern 100, a gate electrode 120, a first source/drain pattern 150, a second source/drain pattern 250, a first frontside source/drain contact 170, a first backside source/drain contact 270, a second backside source/drain contact 470, a gate contact 180, a frontside wiring line 205, a backside connection via 310, and a backside wiring pattern 320.

The semiconductor device, according to example embodiments, may include a first active area AR1, a second active area AR2, and a field area FR.

According to example embodiments, each of the first active area AR1 and the second active area AR2 may extend primarily in a third direction D3. The first active area AR1 and the second active area AR2 may be spaced apart from each other in a second direction D2. The second direction D2 may be a direction crossing the third direction D3. The first active area AR1 and the second active area AR2 may be separated by the field area FR.

According to example embodiments, the field area FR may be disposed between the first active area AR1 and the second active area AR2. The field area FR may form a boundary between the first active area AR1 and the second active area AR2. The field area FR may have a shallow trench isolation (STI) structure. However, this is an example and other arrangements may be used. For example, the field area FR may be defined by a deep trench.

For example, an element separation film may be disposed around the first active area AR1 and the second active area AR2 that are spaced apart from each other. A portion of the element separation film, which is between the first active area AR1 and the second active area AR2, may be the field area FR. For example, a portion at which a channel area of a transistor which may be an example of the semiconductor device is formed may be an active area, or a portion separating the channel area of the transistor, which is formed in the active area, may be a field area. Alternatively, the active area may be a portion at which a fin-shaped pattern or a nano-sheet used as the channel area of the transistor is formed, and the field area may be an area in which the fin-shaped pattern or the nano-sheet used as the channel area is not formed.

As illustrated in FIG. 4, the field area FR may be defined by a trench of a side portion of the base pattern 100, but this is an example and other arrangements may be used. In addition, it is apparent that those skilled in the art to which the present disclosure belongs may distinguish what portion the field area is and what portion the active area is.

As an example, the first active area AR1 and the second active area AR2 may be a p-channel metal-oxide semiconductor (PMOS) formation area. As an example, the first active area AR1 and the second active area AR2 may be an n-channel metal-oxide semiconductor (NMOS) formation area. As still an example, one of the first active area AR1 and the second active area AR2 may be the PMOS formation area, and another one thereof may be the NMOS formation area.

According to example embodiments, the base pattern 100 may be disposed on a first backside inter-layer insulation film 290. The base pattern 100 may be disposed below a first active pattern AP1 and a second active pattern AP2. For example, the base pattern 100 may be disposed between the first backside inter-layer insulation film 290 and the first active pattern AP1. The base pattern 100 may be dispose between the first backside inter-layer insulation film 290 and the second active pattern AP2.

As an example, the base pattern 100 may include a semiconductor material. The base pattern 100 may be a silicon substrate or silicon-on-insulator (SOI). The base pattern 100 may include silicon germanium on insulator (SGOI), indium antimonide, lead telluride, indium arsenide, gallium arsenide, or gallium antimonide, but this is an example and other chemicals and materials may be used. As an example, the base pattern 100 may include at least one of silicon 0oxide, silicon nitride, silicon oxynitride, and a low-permittivity material. As used herein, the low permittivity material may refer to a dielectric material that has a low dielectric constant (k-value) compared to traditional materials like silicon dioxide (SiO₂). The dielectric constant is a measure of a material's ability to store electrical energy in an electric field.

According to example embodiments, a supporter 110 may be disposed in the base pattern 100. The supporter 110 may be surrounded by the base pattern 100. The supporter 110 may be disposed below a portion of the first source/drain pattern 150 and the second source/drain pattern 250. For example, the supporter 110 may be disposed below the first source/drain pattern 150 and the second source/drain pattern 250 to which backside source/drain contacts 270 and 470 are not connected. The supporter 110 may include, for example, germanium.

According to example embodiments, the first active area AR1 may include the first active pattern AP1. The second active area AR2 may include the second active pattern AP2. Each of the first active pattern AP1 and the second active pattern AP2 may be elongated in the third direction D3. For example, they may each extent primarily in the third direction D3 such that their longest dimension runs in this particular direction. The first active pattern AP1 and the second active pattern AP2 may each be multichannel active patterns. For example, each of the first active pattern AP1 and the second active pattern AP2 may each include a plurality of nano-sheets. In the semiconductor device, according to example embodiments, the first active pattern AP1 and the second active pattern AP2 may be active patterns including a nano-sheet or a nanowire.

According to example embodiments, the first active pattern AP1 and the second active pattern AP2 may be disposed on the base pattern 100. The first active pattern AP1 and the second active pattern AP2 may each be spaced apart from the base pattern 100 in a first direction D1. The first active pattern AP1 and the second active pattern AP2 may be disposed on a frontside 100FS of the base pattern.

Here, the third direction D3 may cross the second direction D2 and the first direction D1. Also, the second direction D2 may cross the first direction D1. The first direction D1 may be a thickness-wise direction of the base pattern 100. The first direction D1 may be a direction in which a plurality of first active patterns AP1 or a plurality of active patterns AP2 is disposed on the base pattern.

According to example embodiments, each of the first active pattern AP1 and the second active pattern AP2 may include an upper surface and a lower surface opposite to each other in the first direction D1. The lower surface of each of the first active pattern AP1 and the second active pattern AP2 may face the base pattern 100. Each of the first active pattern AP1 and the second active pattern AP2 is illustrated as including three nano-sheets disposed in the first direction D1. However, this is an example and other arrangements may be used.

For example, a width of a sheet pattern of the first active pattern AP1 in the direction D2 may become larger or smaller in proportion to a width, in the second direction D2, of the base pattern 100 disposed below the first active pattern AP1. Widths of a plurality of sheet patterns of the first active pattern AP1 in the second direction D2 are illustrated as being equal, but it is an example and they may differ in width.

According to example embodiments, the first active pattern AP1 and the second active pattern AP2 may include, for example, silicon or germanium that is an elemental semiconductor material. In addition, the first active pattern AP1 and the second active pattern AP2 may include a compound semiconductor, for example, may include a group IV-IV compound semiconductor or a group III-V compound semiconductor.

The group IV-IV compound semiconductor may be a binary compound or a ternary compound including at least two of carbon (C), silicon (Si), germanium (Ge), and tin (Sn) or may be a compound obtained by doping the above-described compounds with a group IV element.

The group III-V compound semiconductor may be, for example, one of a binary compound, a ternary compound, or a quaternary compound formed in combination of at least one of aluminum (Al), gallium (Ga), and indium (In) of group III elements and one of phosphorus (P), arsenic (As), and antimony (Sb) of group V elements.

According to example embodiments, since a description of the first active pattern AP1 and a description of the second active pattern AP2 are substantially identical, the first active pattern AP1 mainly described hereinafter and it may be understood that the description thereof applies equally to the second active pattern AP2.

According to example embodiments, a field insulation film 105 may be disposed in the field area FR. The field insulation film 105 may be disposed on the base pattern 100. For example, the field insulation film 105 may be disposed between a portion of the base pattern 100, which overlaps the first active pattern AP1 in the first direction D1 and a portion of the base pattern 100, which overlaps the second active pattern AP2 in the first direction D1. The field insulation film 105 may fill at least a portion of a trench formed on the base pattern 100.

According to example embodiments, the field insulation film 105 may cover a side wall of the base pattern 100. A frontside 105FS of the field insulation film and the frontside 100FS of the base pattern may be disposed on the same plane. The frontside 105FS of the field insulation film may be a surface of the field insulation film 105, which faces a first frontside inter-layer insulation film 190. As an example, the field insulation film 105 may cover a portion of the side wall of the base pattern 100. In such a case, a portion of the base pattern 100 may protrude in the first direction further than the field insulation film 105. For example, the field insulation film 105 may include an oxide film, a nitride film, an oxynitride film, or a film in combination thereof. The field insulation film 105 is illustrated as a single film, but it is shown for convenience for description, and it is an example. Other arrangements may be used. According to example embodiments, the field insulation film 105 and the base pattern 100 may include an identical insulation material. In this case, a boundary between the field insulation film 105 and the base pattern 100 might not be identified, and all of the field insulation film 105 and the base pattern 100 may be together referred to as an insulation layer.

According to example embodiments, a gate structure GS may be disposed on the frontside 100FS of the base pattern. Each gate structure GS may extend primarily in the second direction D2. According to example embodiments, the gate structure GS may extend primarily in the second direction D2 across the first active area AR1 and the second active area AR2. Gate structures GS may be spaced apart from one another in the third direction D3. The gate structures GS may be adjacent to each other in the third direction D3.

According to example embodiments, the gate structure GS may be disposed on the first active pattern AP1 and the second active pattern AP2. For example, the gate structure GS may cross the first active area AP1 and the second active area AP2.

According to example embodiments, the gate structures GS may individually surround the first active patterns AP1. The gate structures GS may individually surround the second active patterns AP2. For example, each gate electrode 120 may surround the plurality of sheet patterns included in the first active pattern AP1 and a plurality of sheet patterns included in the second active pattern AP2.

According to example embodiments, the gate structure GS may include the gate electrode 120, a gate insulation film 130, a gate spacer 140, and a gate capping film 145.

According to example embodiments, the gate electrode 120 of the gate structure GS may be disposed across the first active area AR1 and the second active area AR2. For example, the gate electrode 120 which is not adjacent to the backside connection via 310 in the third direction D3 may extend primarily across the first active area AR1 and the second active area AR2.

According to example embodiments, the gate electrode 120 of the gate structure GS might not be continuously extended across the first active area AR1 and the second active area AR2 in the second direction D2 and may be separated in the field area FR. For example, the gate electrode 120, which is adjacent to the backside connection via 310 in the third direction D3, may be cut by a gate separation structure 125 in the field area FR. In such a case, the gate structure GS, which is extended in the second direction D2 and crosses the first active area AR1, and the gate structure GS, which is extended in the second direction D2 and crosses the second active area AR2, may be spaced apart from each other in the second direction.

According to example embodiments, the gate structure GS may include a plurality of inner gate structures I_GS disposed between the first active patterns AP1 which are adjacent in the first direction D1 and between the base pattern 100 and the first active pattern AP1. An inner gate structure I_GS may be disposed between the frontside 100FS of the base pattern and the lower surface of the first active pattern AP1 and between the upper surface of the first active pattern AP1 and the lower surface of the first active pattern AP1 which face each other in the first direction.

According to example embodiments, the number of the inner gate structures I_GS may be equal to the number of the first active patterns AP1. The inner gate structure I_GS is connected to the frontside FS of the base pattern, the upper surface of the first active pattern AP1, and the lower surface of the first active pattern AP1. The inner gate structure I_GS may be connected to the first source/drain pattern 150 or the second source/drain pattern 250 which will be described below.

According to example embodiments, the inner gate structure I_GS may include the gate electrode 120 and the gate insulation film 130, which are disposed between the first active patterns AP1 adjacent in the first direction D1 and between the base pattern 100 and the first active pattern AP1. According to example embodiments, the inner gate structure I_GS may be disposed between the second active patterns AP2 which are adjacent in the first direction D1 and between the base pattern 100 and the second active pattern AP2.

According to example embodiments, the gate electrode 120 may extend primarily in the second direction D2. The gate electrode 120 may be disposed between first source/drain patterns 150 adjacent to each other in the third direction D3. The gate electrode 120 may be disposed between second source/drain patterns 250 adjacent to each other in the third direction D3. Gate electrodes 120 may be spaced apart from each other in the third direction D3.

According to example embodiments, the gate electrode 120 may be connected to the gate contact 180. For example, the gate electrode 120 may overlap the gate contact 180 in the first direction D1 in the first active area AR1, the second active area AR2, or the field area FR.

According to example embodiments, the gate electrode 120 may cross the base pattern 100 and the field insulation film 105. The gate electrode 120 may surround the first active pattern AP1 and the second active pattern AP2. The gate electrode 120 may be disposed on the frontside 100FS of the base pattern in the first active area AR1 and the second active area AR2.

According to example embodiments, the gate electrode 120 may include at least one of a metal, a metal alloy, a conductive metallic nitride, a metallic silicide, a doped semiconductor material, a conductive metallic oxide, and a conductive metallic oxynitride. The gate electrode 120 may include, for example, at least one of titanium nitride (TiN), a tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but it is an example. The conductive metallic oxide and the conductive metallic oxynitride may include a form in which the above-described substance is oxidized, but it is an example and other materials may be used.

According to example embodiments, the gate electrode 120 may be disposed at both sides of the first source/drain pattern 150 which will be described below and both sides of the second source/drain pattern 250 which will be described below. The gate structure GS may be disposed at both sides of the first source/drain pattern 150 and both sides of the second source/drain pattern 250 in the third direction D3.

According to example embodiments, All the gate electrodes 120 which are disposed at both side of the first source/drain pattern 150 may be a normal gate electrode used as a gate of the transistor. As an example, the gate electrode 120, which is disposed at a side of the first source/drain pattern 150, may be used as the gate of the transistor, but the gate electrode 120, which is disposed at another side of the first source/drain pattern 150, may be a dummy gate electrode.

According to example embodiments, the gate insulation film 130 may extend primarily along an upper surface of the field insulation film 105 and an upper surface of the base pattern 100. The gate insulation film 130 may surround the first active pattern AP1 and the second active pattern AP2. The gate electrode 120 may be disposed on the gate insulation film 130. The gate insulation film 130 may be disposed between the gate electrode 120 and the first active pattern AP1. The gate insulation film 130 may be disposed between the gate electrode 120 and the second active pattern AP2.

According to example embodiments, a portion of the gate insulation film 130 may be disposed between the plurality of nano-sheets of the first active patterns AP1 adjacent in the first direction D1 and between the base pattern 100 and a nano-sheet of the first active pattern AP1 which is adjacent to the base pattern 100 in the first direction D1.

According to example embodiments, the gate insulation film 130 may include silicon oxide, silicon-germanium oxide, germanium oxide, silicon oxynitride, silicon nitride, or a high-permittivity material having a dielectric constant higher than that of silicon oxide. The high-permittivity material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

FIGS. 2, 3, and 5 illustrate that the gate insulation film 130 is a single film, but it is for convenience for description, and it is an example. Other arrangements may be used. The gate insulation film 130 may include a plurality of films. The gate insulation film 130 may include a high-permittivity insulation film and an interfacial layer that is disposed between the gate electrode 120 and the first active pattern AP1 or the second active pattern AP2. The interfacial layer may include silicon oxide, and the high-permittivity insulation film may include at least one of the above-described high-permittivity materials.

The semiconductor device, according to example embodiments, may include a negative capacitance (NC) field effect transistor (FET) that uses a negative capacitor. For example, the gate insulation film 130 may include a ferroelectric material film having a ferroelectric characteristic and a paraelectric material film having a paraelectric characteristic.

The ferroelectric material film may have negative capacitance, and the paraelectric material film may have positive capacitance. For example, when two or more capacitors are connected in series, and when capacitance of each of the capacitors has a positive value, total capacitance is decreased below capacitance of each individual capacitor. In contrast, when at least one of the two or more capacitors connected in series has a negative capacitance value, the total capacitance may be larger than an absolute value of capacitance of each individual capacitor while having a positive value.

According to example embodiments, when the ferroelectric material film having the negative capacitance and the paraelectric material film having the positive capacitance are connected in series, a total capacitance value of the ferroelectric material film and the paraelectric material film connected in series may be increased. A transistor having the ferroelectric material film may have a subthreshold swing (SS) less than 60 millivolts (mV)/decade at room temperature by using an increase in the total capacitance value.

The ferroelectric material film, according to example embodiments, may have the ferroelectric characteristic. The ferroelectric material film may include, for example, at least one of hafnium oxide, hafnium zirconium oxide, barium strontium titanium oxide, barium titanium oxide, and lead zirconium titanium oxide. Here, as an example, hafnium zirconium oxide is a material obtained by doping hafnium oxide with zirconium (Zr). As an example, hafnium zirconium oxide may be a compound of hafnium (Hf), zirconium (Zr), and oxygen (O).

The ferroelectric material film, according to example embodiments, may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A type of the dopant included in the ferroelectric material film may vary depending on what ferroelectric material the ferroelectric material film includes.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant according to example embodiments is aluminum (Al), the ferroelectric material film may include 3 to 8 at % (atomic percent) of aluminum. Here, a ratio of the dopant may be a ratio of aluminum to a sum of hafnium and aluminum.

When the dopant according to example embodiments is silicon (Si), the ferroelectric material film may include 2 to 10 at % of silicon. When the dopant is yttrium (Y), the ferroelectric material film may include 2 to 10 at % of yttrium. When the dopant is gadolinium (Gd), the ferroelectric material film may include 1 to 7 at % of gadolinium. When the dopant is zirconium (Zr), the ferroelectric material film may include 50 to 80 at % of zirconium.

The paraelectric material film, according to example embodiments, may have the paraelectric characteristic. The paraelectric material film may include, for example, at least one of silicon oxide and a metallic oxide having high-permittivity. The metallic oxide included in the paraelectric material film may include, for example, at least one of hafnium oxide, zirconium oxide, and aluminum oxide, but it is an example.

The ferroelectric material film and the paraelectric material film, according to example embodiments, may include an identical material. The ferroelectric material film may have the ferroelectric characteristic, but the paraelectric material film might not have the ferroelectric characteristic. For example, when the ferroelectric material film and the paraelectric material film include hafnium oxide, a crystal structure of the hafnium oxide which is included in the ferroelectric material film may be different from a crystal structure of the hafnium oxide which is included in the paraelectric material film.

The ferroelectric material film, according to example embodiments, may have a thickness showing the ferroelectric characteristic. The thickness of the ferroelectric material film may be, for example, 0.5 to 10 nanometers (nm), but it is an example. Since respective threshold thicknesses of ferroelectric materials, which show the ferroelectric characteristic, may be different, the thickness of the ferroelectric material film may vary depending on a ferroelectric material.

As an example, the gate insulation film 130 may include one ferroelectric material film. As an example, the gate insulation film 130 may include a plurality of ferroelectric material films spaced apart from each other. The gate insulation film 130 may have a stack structure in which the plurality of ferroelectric material films and a plurality of paraelectric material films are alternately stacked.

According to example embodiments, the gate spacer 140 may be disposed on a side wall of the gate electrode 120. The gate spacer 140 might not be disposed between the base pattern 100 and the first active pattern AP1 and between the plurality of nano-sheets of the first active patterns AP1 adjacent in the first direction D1.

According to example embodiments, the gate spacer 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and a combination thereof. The gate spacer 140 is illustrated as a single film, but it is for convenience for description, and it is an example.

According to example embodiments, an inner gate spacer may be disposed between the first source/drain pattern 150 and a gate insulation layer 130which is between the base pattern 100 and the first active pattern AP1 and between the plurality of nano-sheets of the first active patterns AP1 adjacent in the first direction D1. The inner gate spacer may include at least one of the above-described materials of the gate spacer 140. The inner gate spacer may include a material identical to or different from that of the gate spacer 140.

According to example embodiments, the gate capping film 145 may be disposed on the gate electrode 120 and the gate spacer 140. An upper surface of the gate capping film 145 and an upper surface of the first frontside inter-layer insulation film 190 may be disposed on the same plane. The gate capping film 145 may be disposed between gate spacers 140. In such a case, the upper surface of the gate capping film 145 and an upper surface of the first frontside inter-layer insulation film 190 may be disposed on the identical plane.

According to example embodiments, the gate capping film 145 may include, for example, at least one of silicon nitride (SiN), silicon oxynitride (SiON), silicon carbonitride (SiCN), silicon oxycarbonitride (SiOCN), and a combination thereof. The gate capping film 145 may include a material having an etch selectivity for the first frontside inter-layer insulation film 190.

According to example embodiments, the gate separation structure 125 may be adjacent to the backside connection via 310 in the third direction D3. The gate separation structure 125 may overlap the backside connection via 310 in the third direction D3. The gate separation structure 125 may be disposed on the backside wiring pattern 320. The gate separation structure 125 may be partially inserted into the backside wiring pattern 320. For example, a backside 125BS of the gate separation structure may be disposed below a frontside 322FS of a second portion of the backside wiring pattern 320. The frontside 322FS of the backside wiring pattern 320 may be closer to the frontside 105FS of the field insulation film than the backside 125BS of the gate separation structure.

According to example embodiments, the gate separation structure 125 may cut the gate electrode 120 which is adjacent to the backside connection via 310 in the third direction D3. The gate separation structure 125 may separate, in the second direction D2, the gate electrode 120 extended across the first active area AR1 and the second active area AR2 in the second direction D2. The gate electrode 120 may be separated by the gate separation structure 125 into the gate electrode 120 which surrounds the first active pattern AP1 in the first active area AR1 and the gate electrode 120 which surrounds the second active pattern AP2 in the second active area AR2.

FIG. 3 illustrates that the gate separation structure 125 is disposed at both sides of the backside connection via 310 in the third direction D3, but it is an example. For example, the gate separation structure 125 might not be disposed at both sides of the backside connection via 310 in the third direction D3. In such a case, at least a portion of the backside connection via 310 and the first frontside source/drain contact 170, which is connected to the backside connection via 310, may be disposed between the gate structures GS, which are at both sides thereof.

According to example embodiments, the first source/drain pattern 150 may be disposed in the first active area AR1. The second source/drain pattern 250 may be disposed in the second active area AR2.

According to example embodiments, the first source/drain pattern 150 and the second source/drain pattern 250 may have an identical conductivity type. The first source/drain pattern 150 and the second source/drain pattern 250 may have N type. The first source/drain pattern 150 and the second source/drain pattern 250 may include an N-type dopant. The N-type dopant may include at least one of phosphorus (P), arsenic (As), antimony (Sb), and bismuth (Bi), but it is an example and other N-type dopants may be used. As an example, the first source/drain pattern 150 and the second source/drain pattern 250 may have P type. The first source/drain pattern 150 and the second source/drain pattern 250 may include a P-type dopant. The P-type dopant may include at least one of boron (B) and gallium (Ga). However, as an example, the first source/drain pattern 150 and the second source/drain pattern 250 may have different conductivity types.

According to example embodiments, the first source/drain pattern 150 may be connected to the first active pattern AP1. The first source/drain pattern 150 may be disposed between the first active patterns AP1 in the third direction D3. The first source/drain pattern 150 may be disposed between the gate electrodes 120 which are adjacent to each other in the third direction D3. The first source/drain pattern 150 may be disposed on the base pattern 100.

According to example embodiments, the first source/drain pattern 150 may be a source/drain of a transistor using the first active pattern AP1 as a channel area. The first source/drain pattern 150 may be connected to the first active pattern AP1 in the third direction D3. The first source/drain pattern 150 may be disposed at both sides of the first active pattern AP1 in the third direction D3.

According to example embodiments, the second source/drain pattern 250 may be a source/drain of a transistor using the second active pattern AP2 as a channel area. The second source/drain pattern 250 may be connected to the second active pattern AP2 in the third direction D3. The second source/drain pattern 250 may be disposed at both sides of the second active pattern AP2 in the third direction D3.

According to example embodiments, each of the first source/drain pattern 150 and the second source/drain pattern 250 may include an epitaxial pattern. Each of the first source/drain pattern 150 and the second source/drain pattern 250 may include a semiconductor material.

According to example embodiments, a source/drain etch stop film 160 may extend primarily along an outer side wall of the gate spacer 140, a side wall of the first source/drain pattern 150, and a side wall of the second source/drain pattern 250. The source/drain etch stop film 160 may extend primarily along the frontside 105FS of the field insulation film. The source/drain etch stop film 160 is illustrated as being extended along a side wall of the gate capping film 145, but it is an example.

According to example embodiments, the source/drain etch stop film 160 may include at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), and a combination thereof.

According to example embodiments, the first frontside inter-layer insulation film 190 may be disposed on the source/drain etch stop film 160. The first frontside inter-layer insulation film 190 may be disposed on the first source/drain pattern 150 and the second source/drain pattern 250.

According to example embodiments, the first frontside inter-layer insulation film 190 might not cover an upper surface of the gate structure GS. For example, the first frontside inter-layer insulation film 190 and the upper surface of the gate structure GS may be disposed on the same plane.

According to example embodiments, the first frontside inter-layer insulation film 190 may include, for example, at least one of silicon oxide, silicon nitride, silicon oxynitride, and a low-permittivity material. The low-permittivity material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but it is an example.

According to example embodiments, the first frontside source/drain contact 170 may be disposed on the first source/drain pattern 150 and the second source/drain pattern 250 above the frontside 100FS of the base pattern. The first frontside source/drain contact 170 may be connected to the first source/drain pattern 150 and the second source/drain pattern 250. The first frontside source/drain contact 170 may electrically connect the first source/drain pattern 150 and the second source/drain pattern 250. The first frontside source/drain contact 170 may passing through the source/drain etch stop film 160 to be connected to the first source/drain pattern 150 and the second source/drain pattern 250.

According to example embodiments, the first frontside source/drain contact 170 may be disposed in the first frontside inter-layer insulation film 190. The first frontside source/drain contact 170 may be surrounded by the first frontside inter-layer insulation film 190. The first frontside inter-layer insulation film 190 might not cover an upper surface of the first frontside source/drain contact 170. As an example, the upper surface of the first frontside source/drain contact 170 might not protrude above the upper surface of the gate structure GS. The upper surface of the first frontside source/drain contact 170 and the upper surface of the gate structure GS may be disposed on a same plane. As an example, the upper surface of the first frontside source/drain contact 170 may protrude above the upper surface of the gate structure GS.

According to example embodiments, the first frontside source/drain contact 170 may be connected to the backside connection via 310. The first frontside source/drain contact 170 may overlap the backside connection via 310 in the field area FR in the first direction D1. The first frontside source/drain contact 170 may be connected to the backside wiring pattern 320 through the backside connection via 310.

According to example embodiments, a first frontside silicide film 175 may be disposed between the first frontside source/drain contact 170 and the first source/drain pattern 150. The first frontside silicide film 175 may be disposed between the first frontside source/drain contact 170 and the second source/drain pattern 250. The first frontside silicide film 175 is illustrated as being formed along a profile of a boundary surface between the first source/drain pattern 150 and the first frontside source/drain contact 170, but it is an example. The first frontside silicide film 175 may include, for example, a metallic silicide material.

According to example embodiments, the first frontside source/drain contact 170 may include a frontside source/drain contact barrier film 170a and a frontside source/drain contact filling film 170b disposed on the frontside source/drain contact barrier film 170a. The frontside source/drain contact barrier film 170a may extend primarily along a side wall and a floor surface of the frontside source/drain contact filling film 170b.

FIGS. 1 and 5 illustrate that the first frontside source/drain contact 170 is extended across the first active area AR1, the second active area AR2, and the field area FR in the second direction D2, but it is an example. As an example, the first frontside source/drain contact 170 may be connected to the first source/drain pattern 150 in the first active area AR1 and might not extend primarily to the field area FR and the second active area AR2. As an example, the first frontside source/drain contact 170 may be connected to the second source/drain pattern 250 in the second active area AR2 and might not extend primarily to the first active area AR1.

According to example embodiments, from the frontside 100FS of the base pattern, an upper surface of the frontside source/drain contact barrier film 170a is illustrated as being positioned at a height substantially equal to that of an upper surface of the frontside source/drain contact filling film 170b, but it is an example. From the frontside 100FS of the base pattern, the upper surface of the frontside source/drain contact barrier film 170a may be lower than the upper surface of the frontside source/drain contact filling film 170b.

According to example embodiments, the frontside source/drain contact barrier film 170a may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material. In the semiconductor device according to example embodiments, the two-dimensional material may be a metallic material and/or a semiconductor material. The 2D material may include a two-dimensional allotrope or a two-dimensional compound and include, for example, at least one of graphene, molybdenum disulfide (MoS₂), molybdenum diselenide (MoSe₂), tungsten diselenide (WSe₂), and tungsten disulfide (WS₂), but it is an example. For example, since the above-described 2D materials are mentioned as an example, a 2D material that may be included in the semiconductor device of the present disclosure is not limited to the above-described materials.

According to example embodiments, the frontside source/drain contact filling film 170b may include, for example, at least one of aluminum (Al), tungsten (W), cobalt (Co), ruthenium (Ru), silver (Ag), gold (Au), manganese (Mn), and molybdenum (Mo).

According to example embodiments, the first frontside source/drain contact 170 is illustrated as including a plurality of conductive films, but it is an example. The first frontside source/drain contact 170 may be a single film.

According to example embodiments, each of the first backside source/drain contact 270 and the second backside source/drain contact 470 may be disposed below the first source/drain pattern 150 and the second source/drain pattern 250 and on a backside 100BS of the base pattern. The first backside source/drain contact 270 may penetrate the base pattern 100 from the backside 100BS of the base pattern to be connected to the first source/drain pattern 150. The second backside source/drain contact 470 may penetrate the base pattern 100 from the backside 100BS of the base pattern to be connected to the second source/drain pattern 250.

According to example embodiments, the first backside source/drain contact 270 and the second backside source/drain contact 470 may be disposed on the backside wiring pattern 320. The first backside source/drain contact 270 and the second backside source/drain contact 470 may be connected to the backside wiring pattern 320. The first backside source/drain contact 270 and the second backside source/drain contact 470 may be connected to the backside wiring pattern 320. The first backside source/drain contact 270 and the second backside source/drain contact 470 may be disposed on a first portion 321 of the backside wiring pattern 320. The first backside source/drain contact 270 and the second backside source/drain contact 470 may be connected to the first portion 321 of the backside wiring pattern 320.

According to example embodiments, a first backside silicide film 275 may be disposed between the first backside source/drain contact 270 and the first source/drain pattern 150. A second backside silicide film 475 may be disposed between the second backside source/drain contact 470 and the second source/drain pattern 250. The first backside silicide film 275 is illustrated as being formed along a profile of a boundary surface between the first source/drain pattern 150 and the first backside source/drain contact 270, and the second backside silicide film 475 is illustrated as being formed along a profile of a boundary surface between the second source/drain pattern 250 and the second backside source/drain contact 470. However, it is an example. The first backside silicide film 275 and the second backside silicide film 475 may include, for example, a metallic silicide material.

FIGS. 2 and 4 illustrate that the first backside source/drain contact 270 and the second backside source/drain contact 470 are single films, but it is an example. For example, the first backside source/drain contact 270 and the second backside source/drain contact 470 may have a multi-film structure including a barrier film and a filling film, such as the first frontside source/drain contact 170.

According to example embodiments, a description for a material included in the first backside source/drain contact 270 and the second backside source/drain contact 470 may be substantially identical to the above description for a material included in the first frontside source/drain contact 170. For example, each of the first backside source/drain contact 270 and the second backside source/drain contact 470 may include at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), the two-dimensional (2D) material, aluminum (Al), tungsten (W), cobalt (Co), ruthenium (Ru), silver (Ag), gold (Au), manganese (Mn), and molybdenum (Mo).

According to example embodiments, the gate contact 180 may be disposed on the gate electrode 120 above the frontside 100FS of the base pattern. The gate contact 180 may penetrate the gate capping film 145 to be connected to the gate electrode 120. The gate contact 180 may penetrate a first frontside etch stop film 196 and a second frontside inter-layer insulation film 191. The gate contact 180 may be connected to the frontside wiring line 205.

As an example, an upper surface of the gate contact 180 may protrude above the upper surface of the gate structure GS. As an example, the upper surface of the gate contact 180 and the upper surface of the gate structure GS may be disposed on the same plane.

According to example embodiments, the gate contact 180 may include a gate contact barrier film 180a and a gate contact filling film 180b on the gate contact barrier film 180a. A description for a material included in the gate contact barrier film 180a and a gate contact filling film 180b may be identical to a description for a material included in the frontside source/drain contact barrier film 170a and the frontside source/drain contact filling film 170b.

According to example embodiments, the first frontside etch stop film 196 may be disposed on the first frontside inter-layer insulation film 190, the gate structure GS, and the first frontside source/drain contact 170. The second frontside inter-layer insulation film 191 may be disposed on the first frontside etch stop film 196.

According to example embodiments, the first frontside etch stop film 196 may include a material having an etch selectivity for the second frontside inter-layer insulation film 191. The first frontside etch stop film 196 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), aluminum oxide (AlO), aluminum nitride (AlN), and aluminum oxycarbide (AlOC), and a combination thereof. The first frontside etch stop film 196 is illustrated as a single film, but it is an example. The first frontside etch stop film 196 might not be formed. The second frontside inter-layer insulation film 191 may include, for example, at least one of silicon oxide, silicon nitride, silicon oxynitride, and a low-permittivity material.

According to example embodiments, a second frontside etch stop film 197 may be disposed between the second frontside inter-layer insulation film 191 and a third frontside inter-layer insulation film 192. The second frontside etch stop film 197 may extend primarily along an upper surface of the second frontside inter-layer insulation film contact 191. The third frontside inter-layer insulation film 192 may be disposed on the second frontside etch stop film 197. To the extent that an element is not described in detail with respect to this figure, it may be understood that the element is at least similar to a corresponding element that has been described elsewhere within the present disclosure.

According to example embodiments, the second frontside etch stop film 197 may include a material having an etch selectivity for the third frontside inter-layer insulation film 192. A description for a material included in the second frontside etch stop film 197 may be substantially identical to a description for the first frontside etch stop film 196. A description for the third frontside inter-layer insulation film 192 may be substantially identical to a description for the second frontside inter-layer insulation film 191.

According to example embodiments, a frontside wiring via 185 may be disposed in the second frontside inter-layer insulation film 191. The frontside wiring via 185 may penetrate the first frontside etch stop film 196 to be directly connected to the first frontside source/drain contact 170. The frontside wiring via 185 may connect the first frontside source/drain contact 170 and the frontside wiring line 205.

According to example embodiments, the frontside wiring via 185 may include a frontside via barrier film 185a and a frontside via filling film 185b. The frontside via barrier film 185a may extend primarily along a side wall and a floor surface of the frontside via filling film 185b. The frontside via barrier film 185a may include, for example, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and the two-dimensional (2D) material. The frontside via filling film 185b may include, for example, at least one of aluminum (Al), tungsten (W), cobalt (Co), ruthenium (Ru), copper (Cu), silver (Ag), gold (Au), manganese (Mn), and molybdenum (Mo).

According to example embodiments, the frontside wiring line 205 may be disposed in the third frontside inter-layer insulation film 192. The frontside wiring line 205 may be connected to the gate contact 180. The frontside wiring line 205 may be connected to the first frontside source/drain contact 170 through the first frontside wiring via 185.

According to example embodiments, the frontside wiring line 205 may include a frontside wiring barrier film 205a and a frontside wiring filling film 205b. The frontside wiring barrier film 205a may include, for example, at least one of a metal, a conductive metallic nitride, a conductive metallic carbide, a conductive metallic oxide, a conductive metallic carbonitride, and a 2D material. The frontside wiring filling film 205b may include, for example, at least one of a metal and a metallic alloy. A description for the frontside wiring barrier film 205a and the frontside wiring filling film 205b of the frontside wiring line 205 may be substantially identical to a description for the frontside via barrier film 185a and the frontside via filling film 185b of the frontside wiring via 185. The frontside wiring line 205 is illustrated as having a multi-conductive film structure, but it is an example. The frontside wiring line 205 may have a single-conductive film structure.

According to example embodiments, the backside connection via 310 may be disposed between the first frontside source/drain contact 170 and the backside wiring pattern 320. The backside connection via 310 may extend primarily in the first direction D1 between the first frontside source/drain contact 170 and the backside wiring pattern 320. The backside connection via 310 may connect the first frontside source/drain contact 170 and the backside wiring pattern 320.

According to example embodiments, the backside connection via 310 may be disposed between the first source/drain pattern 150 and the second source/drain pattern 250 in the second direction D2. The backside connection via 310 may penetrate the first frontside inter-layer insulation film 190 between the first source/drain pattern 150 and the second source/drain pattern 250. According to example embodiments, a side wall 310SW of the backside connection via may be surrounded by the first frontside inter-layer insulation film 190. As approaching the backside wiring pattern 320 from the first frontside source/drain contact 170, a width of the backside connection via 310 may be reduced in the second direction D2.

According to example embodiments, the backside connection via 310 may penetrate the source/drain etch stop film 160 to be inserted into the field insulation film 105. The backside connection via 310 may overlap the field insulation film 105, the first backside source/drain contact 270, and the second backside source/drain contact 470 in the second direction D2.

According to example embodiments, a backside 310BS of the backside connection via may be disposed below a backside 150BS of the first source/drain pattern. The backside 310BS of the backside connection via may be closer to the backside 100BS of the base pattern than the backside 150BS of the first source/drain pattern in the first direction D1. The backside 310BS of the backside connection via may be a surface of the backside connection via 310, which is connected to the backside wiring pattern 320. The backside 150BS of the first source/drain pattern may be a surface of the first source/drain pattern 150, which is connected to the base pattern 100.

According to example embodiments, the backside connection via 310 may include, for example, at least one of titanium nitride (TiN), a tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but it is an example.

According to example embodiments, the backside wiring pattern 320 may be disposed on the backside 100BS of the base pattern. The backside wiring pattern 320 may be disposed in the first backside inter-layer insulation film 290. The backside wiring pattern 320 may be connected to the first backside source/drain contact 270 and the second backside source/drain contact 470. The backside wiring pattern 320 may be connected to the first backside source/drain contact 270 and the second backside source/drain contact 470. The backside wiring pattern 320 may be connected to the backside connection via 310. The backside wiring pattern 320 may be connected to the backside connection via 310.

According to example embodiments, the backside wiring pattern 320 may extend primarily in the third direction D3. The backside wiring pattern 320 may have a width in the second direction D2. In the second direction D2, a width W320 of the backside wiring pattern may be larger than a distance D_AP between the first active pattern AP1 and the second active pattern AP2. The width W320 of the backside wiring pattern may refer to a maximum width of the backside wiring pattern 320 in the second direction D2. The distance between D_AP between the first active pattern AP1 and the second active pattern AP2 may refer to a minimum distance between the first active pattern AP1 and the second active pattern AP2 in the second direction D2. The backside wiring pattern 320 may overlap the first active pattern AP1 and the second active pattern AP2 in the first direction D1. For example, the backside wiring pattern 320 may have a width in the second direction D2 across the first active area AR1, the field area, and the second active area AR2.

According to example embodiments, the backside wiring pattern 320 may have the first portion 321 and a second portion 322.

According to example embodiments, the first portion 321 may be disposed below the second portion 322. The first portion 321 may be surrounded by the first backside inter-layer insulation film 290. The first portion 321 may be disposed on the backside 100BS of the base pattern. The first portion 321 may be connected to the first backside source/drain contact 270 and the second backside source/drain contact 470. The first portion 321 may be connected to the first backside source/drain contact 270 and the second backside source/drain contact 470. A first frontside 321FS may be connected to the first backside source/drain contact 270 and the second backside source/drain contact 470. The first frontside 321FS may be a frontside of the first portion 321. The first frontside 321FS may be a surface of the backside wiring pattern 320, which is connected to the first backside source/drain contact 270 or the second backside source/drain contact 470.

According to example embodiments, the second portion 322 may be disposed on the first portion 321. The second portion 322 may protrude from the first portion in the first direction D1. The second portion 322 may be surrounded by the field insulation film 105. The second portion 322 may be connected to the backside connection via 310. The second portion 322 may be connected to the backside connection via 310. A second frontside 322FS may be a frontside of the second portion 322. The second frontside 322FS may be a surface of the backside wiring pattern 320, which is connected to the backside connection via 310. The second frontside 322FS may be a frontside of the backside wiring pattern 320.

According to example embodiments, around the first frontside source/drain contact 170, the first frontside 321FS may be disposed below the second frontside 322FS. The first frontside 321FS may be further spaced apart from the frontside 100FS of the base pattern than the second frontside 322FS in the first direction D1.

According to example embodiments, the second frontside 322FS that is connected to the backside connection via 310 may be disposed between the frontside 100FS of the base pattern and the backside 100BS of the base pattern in the first direction D1. From the backside 100BS of the base pattern, a height of the frontside 322FS of the second portion in the first direction D1 may be smaller than a height of the frontside 100FS of the base pattern. For example, the frontside 322FS of the second portion may be closer to the backside 100BS of the base pattern than the frontside 100FS of the base pattern.

According to example embodiments, in the second direction D2, a width W322FS of the frontside of the second portion 322 connected to the backside connection via 310 may be larger than a width W310BS of the backside of the backside connection via 310 connected to the second portion 322.

According to example embodiments, the backside wiring pattern 320 may include, for example, at least one of titanium nitride (TiN), a tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but it is an example.

In description of the semiconductor device according to example embodiments, FIGS. 2 through 5 illustrate that the backside connection via 310 and the backside wiring pattern 320 are single films, but it is an example. For example, the backside connection via 310 and the backside wiring pattern 320 may have a multi-film structure including a barrier film and a filling film, such as the first frontside source/drain contact 170.

According to example embodiments, the first backside inter-layer insulation film 290 may be disposed below the base pattern 100 and the field insulation film 105. The first backside inter-layer insulation film 290 may surround at least a portion of the backside wiring pattern 320. Since a description for a material included in the first backside inter-layer insulation film 290 may be identical to a description for a material included in the first frontside inter-layer insulation film 190, the description for the material included in the first backside insulation film 290 will be omitted and to the extent that an element is not described in detail with respect to this figure, it may be understood that the element is at least similar to a corresponding element that has been described elsewhere within the present disclosure.

According to example embodiments, the first source/drain pattern 150 and the second source/drain pattern 250 may be connected to the backside wiring pattern 320 through the first frontside source/drain contact 170 and the backside connection via 310 and connected to the backside wiring pattern 320 through the first backside source/drain contact 270 and the second backside source/drain contact 470. The first source/drain pattern 150 and the second source/drain pattern 250 may be electrically connected to the backside wiring pattern 320 through the first frontside source/drain contact 170 and the backside connection via 310. In addition, the first source/drain pattern 150 and the second source/drain pattern 250 may be electrically connected to the backside wiring pattern 320 through the first backside source/drain contact 270 and the second backside source/drain contact 470, respectively. The contact area of each of the first source/drain pattern 150 and the second source/drain pattern 250 increases when all three contacts are used: the first frontside source/drain contact 170, the first backside source/drain contact 270, and the second backside source/drain contact 470. This is in contrast to using only the first frontside source/drain contact 170 or only the first and second backside source/drain contacts 270 and 470. As a result of the increased contact area, the electrical resistance between these patterns and the backside wiring pattern 320 may be reduced.

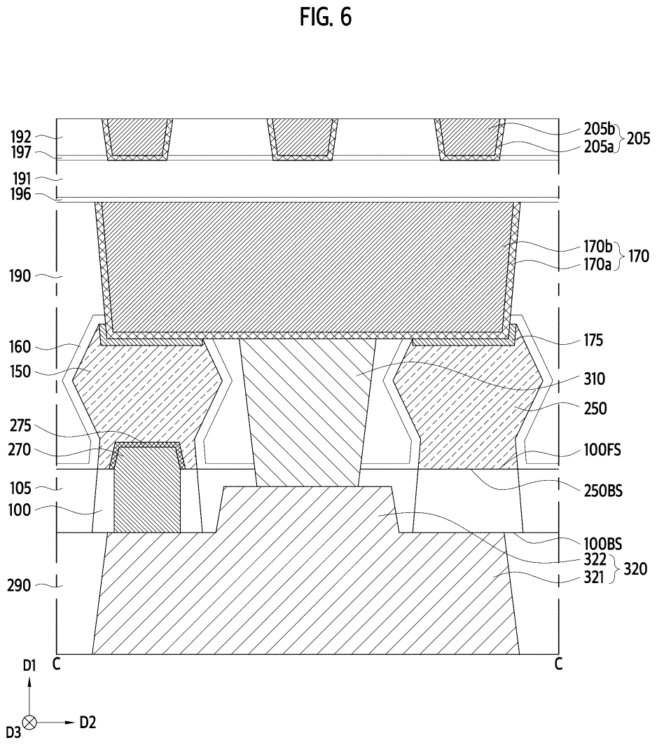

FIG. 6 is an example layout diagram for describing a semiconductor package according to example embodiments. In order to describe the semiconductor package according to example embodiments, a description will mainly focus on a point different from that described above with reference to FIGS. 1 through 5.

Referring to FIG. 6, the second backside source/drain contact 470 (of FIG. 4) might not be disposed below the second source/drain pattern 250. The second source/drain pattern 250 might not be connected to the backside wiring pattern 320 through the second backside source/drain contact 470 (of FIG. 4). The second source/drain pattern 250 may be connected to the backside wiring pattern 320 only through the first frontside source/drain contact 170 and the backside connection via 310. The first source/drain pattern 150 may be electrically connected to the backside wiring pattern 320 through the first backside source/drain contact 270 and connected to the backside wiring pattern 320 also through the first frontside source/drain contact 170 and the backside connection via 310.

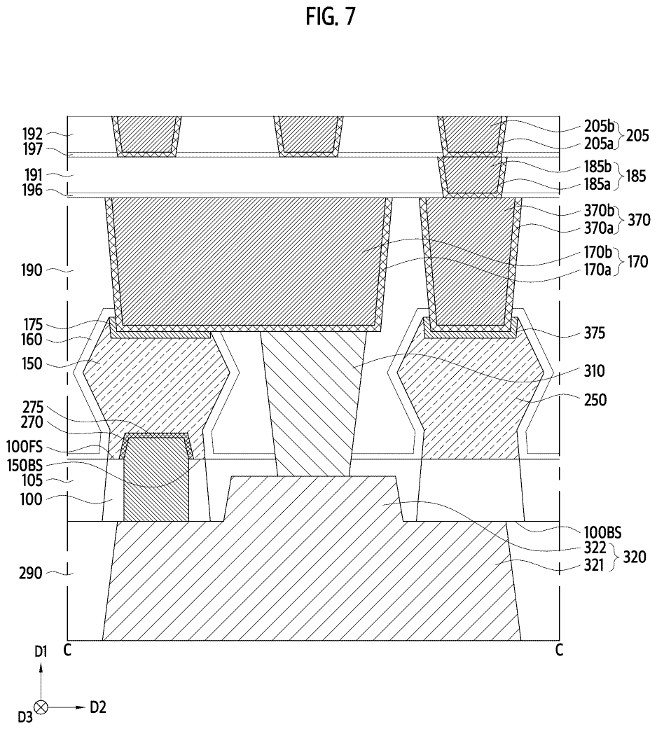

FIG. 7 is a cross-sectional view illustrating a semiconductor device according to example embodiments and illustrates a cross section taken along line C-C of FIG. 1. In order to describe the semiconductor package according to example embodiments, a description will mainly focus on a point different from that described above with reference to FIGS. 1 through 6.

Referring to FIG. 7, the first frontside source/drain contact 170 may be connected to the first source/drain pattern 150 and might not be connected to the second source/drain pattern 250. The first frontside source/drain contact 170 might not overlap the second source/drain pattern 250 in the first direction D1.

According to example embodiments, a second frontside source/drain contact 370 may be disposed on the second source/drain pattern 250. The second frontside source/drain contact 370 may overlap the second source/drain pattern 250 in the first direction D1. The first frontside source/drain contact 170 may be spaced apart from the second frontside source/drain contact 370 in the second direction D2. The first frontside inter-layer insulation film 190 may be disposed between the first frontside source/drain contact 170 and the second frontside source/drain contact 370.

According to example embodiments, the backside connection via 310 may be connected to the first frontside source/drain contact 170. The backside connection via 310 may extend primarily in the first direction D1 between the first frontside source/drain contact 170 and the backside wiring pattern 320. The backside connection via 310 might not be connected to the second frontside source/drain contact 370.

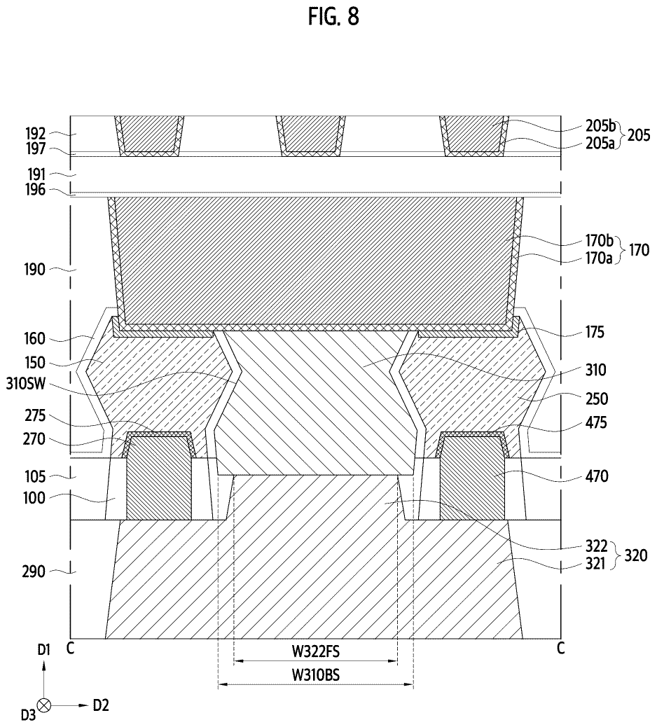

FIG. 8 is a cross-sectional view illustrating a semiconductor device according to example embodiments and illustrates a cross section taken along line C-C of FIG. 1. In order to describe the semiconductor package according to example embodiments, a description will mainly focus on a point different from that described above with reference to FIGS. 1 through 5.

Referring to FIG. 8, the backside connection via 310 may be surrounded by the source/drain etch stop film 160. The side wall 310SW of the backside connection via 310 may be covered with the source/drain etch stop film 160. The backside connection via 310 may be formed along a surface profile of the first source/drain pattern 150, the second source/drain pattern 250, and the source/drain etch stop film 160.

According to example embodiments, the width W322FS of a frontside of the second portion 322 of the backside wiring pattern 320 connected to the backside connection via 310 may be smaller than the width W310BS of a backside of the backside connection via 310 connected to the backside wiring pattern 320.

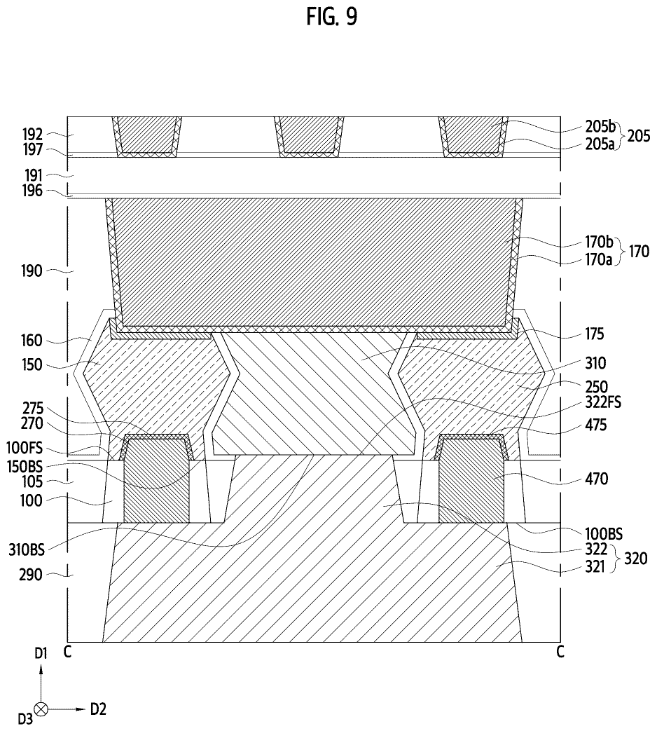

FIG. 9 is a cross-sectional view illustrating a semiconductor device according to example embodiments and illustrates a cross section taken along line C-C of FIG. 1. In order to describe the semiconductor package according to example embodiments, a description will mainly focus on a point different from that described above with reference to FIGS. 1 through 5 and FIG. 8.

Referring to FIG. 9, the backside connection via 310 might not penetrate the source/drain etch stop film 160. The backside connection via 310 may be disposed on the source/drain etch stop film 160. Around the backside 100BS of a base pattern, the backside 310BS of a backside connection via may be disposed above the backside 150BS of a first source/drain pattern. The backside 310BS of the backside connection via may be further spaced apart from the backside 100BS of the base pattern than the backside 150BS of the first source/drain pattern in the first direction D1.

According to example embodiments, the second portion 322 of the backside wiring pattern 320 may penetrate the source/drain etch stop film 160. Around the backside 100BS of the base pattern, the frontside 322FS of the second portion of the backside wiring pattern 320 may be disposed above the backside 150BS of the first source/drain pattern.

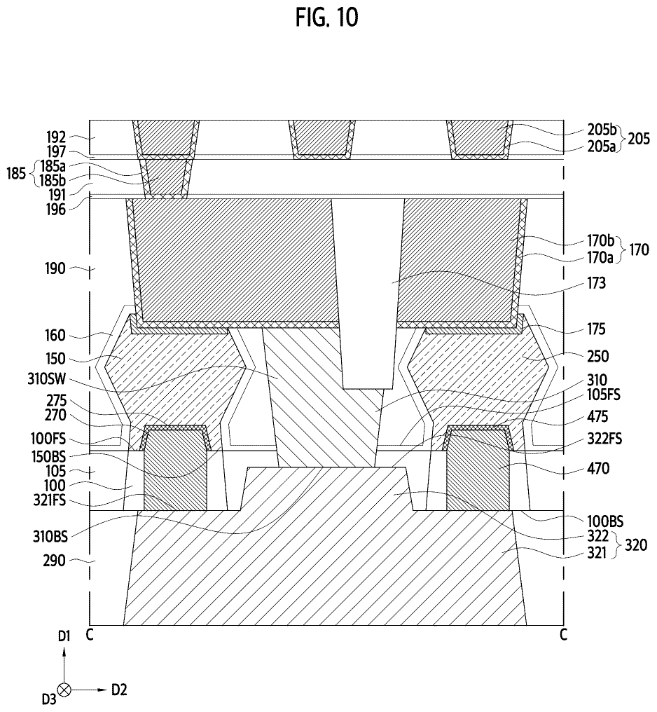

FIG. 10 is a cross section taken along line C-C of FIG. 1 according to example embodiments. In order to describe the semiconductor package according to example embodiments, a description will mainly focus on a point different from that described above with reference to FIGS. 1 through 5.

Referring to FIG. 10, a contact separation structure 173 may be disposed on the backside connection via 310. The contact separation structure 173 may penetrate the first frontside source/drain contact 170. At least a portion of a side wall of the contact separation structure 173 may be surrounded by the frontside source/drain contact filling film 170b. The frontside source/drain contact barrier film 170a might not extend primarily along the side wall of the contact separation structure 173.

According to example embodiments, at least a portion of the contact separation structure 173 may be inserted into the backside connection via 310. The gate separation structure 173 may at least partially overlap the backside connection via 310. At least a portion of the backside connection via 310 may overlap the contact separation structure 173 in the first direction D1. At least a portion of the backside connection via 310 may overlap the contact separation structure 173 in the second direction D2.

According to example embodiments, the contact separation structure 173 may cut the first frontside source/drain contact 170 in the second direction D2. The contact separation structure 173 may separate, in the second direction D2, the first frontside source/drain contact 170 which is disposed across the first source/drain pattern 150 and the second source/drain pattern 250 in the second direction D2.

According to example embodiments, the first frontside source/drain contact 170 may be separated into a portion disposed on the first source/drain pattern 150 and a portion disposed on the second source/drain pattern 250 with the contact separation structure 173 in between.

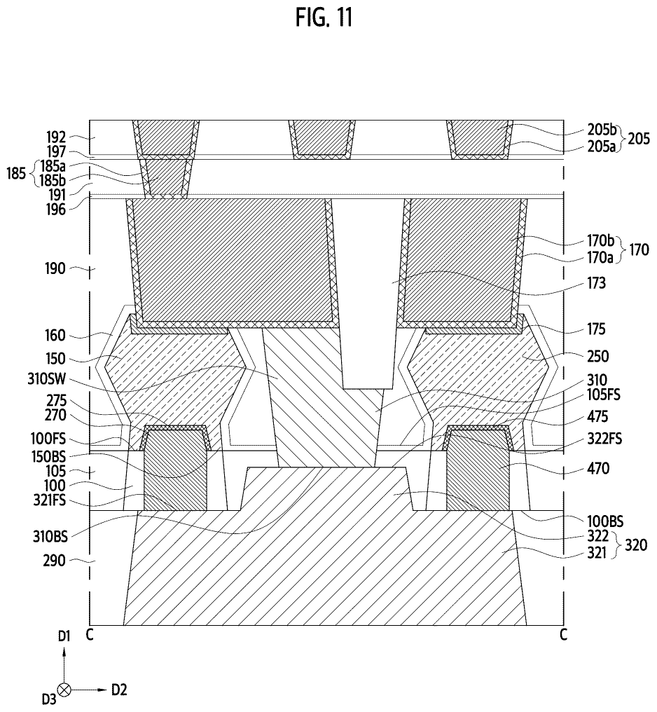

FIG. 11 is a cross section taken along line C-C of FIG. 1 according to example embodiments. In order to describe the semiconductor package according to example embodiments, a description will mainly focus on a point different from that described above with reference to FIGS. 1 through 5 and FIG. 10.

Referring to FIG. 11, the frontside source/drain contact barrier film 170a may extend primarily along at least a portion of a side wall of the contact separation structure 173. The at least a portion of the side wall of the contact separation structure 173 may be surrounded by the frontside source/drain contact barrier film 170a. The contact separation structure 173 for example be connected to the frontside source/drain contact filling film 170b. The frontside source/drain contact barrier film 170a may surround the at least a portion of the side wall of the contact separation structure 173.

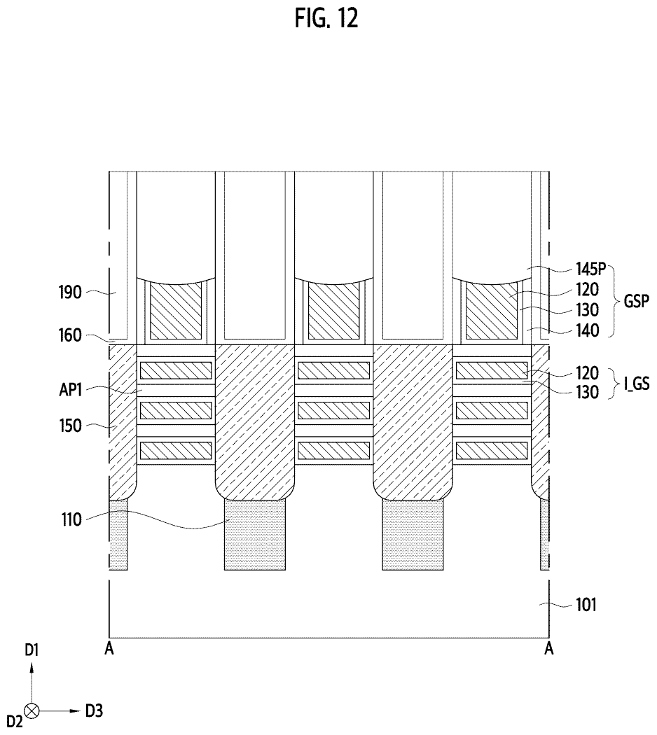

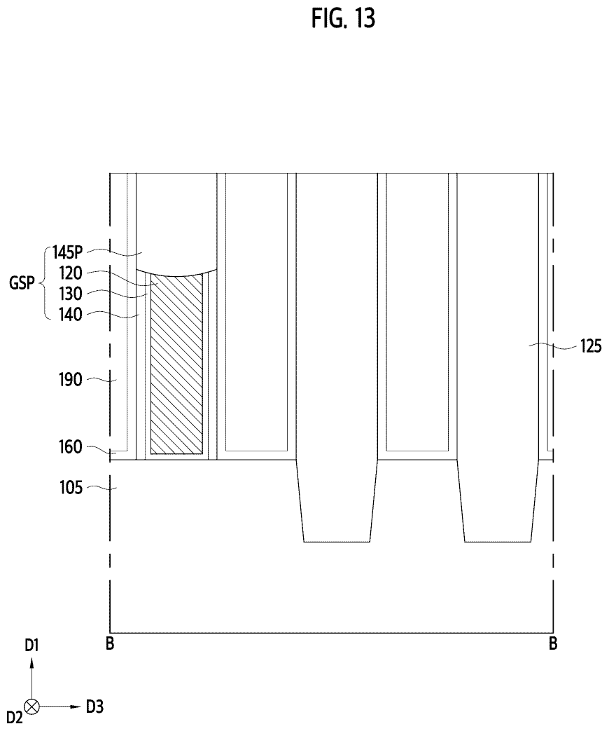

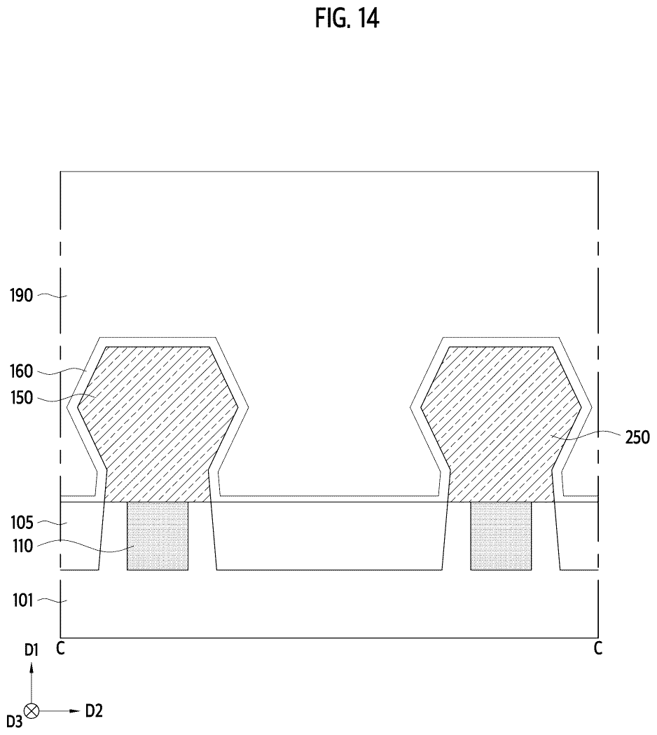

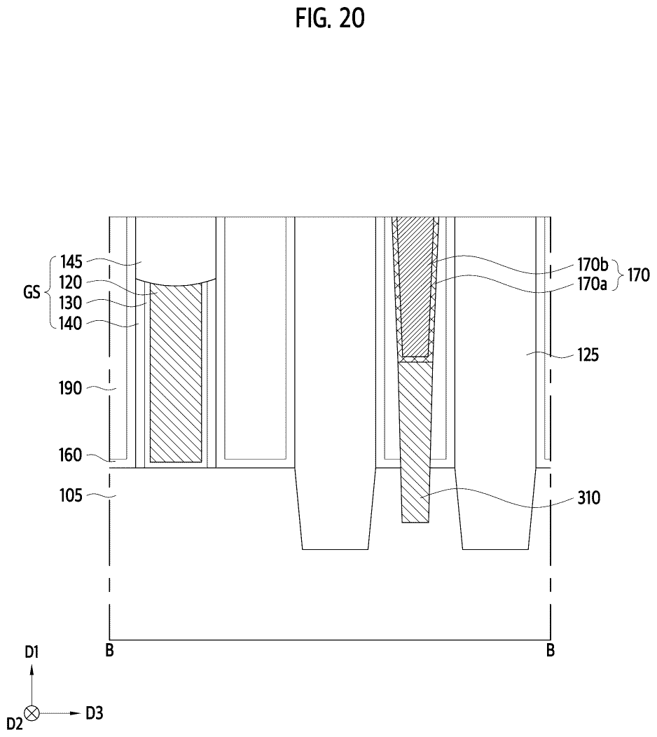

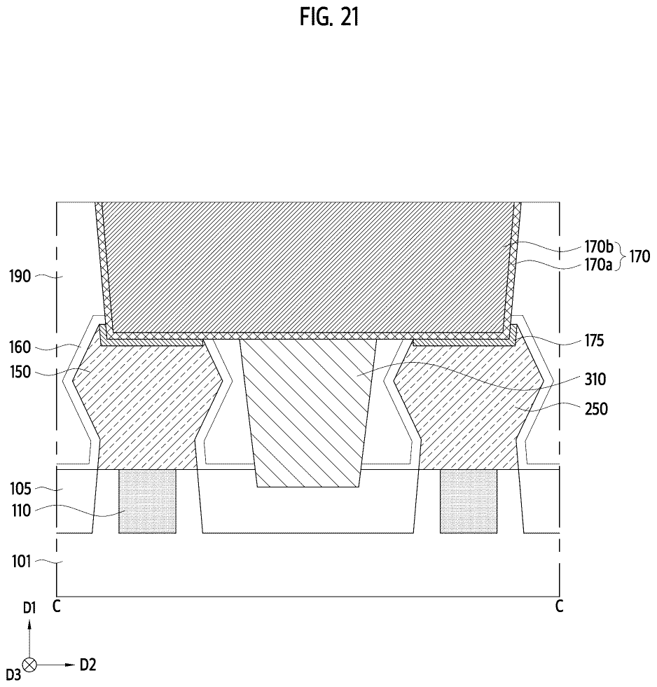

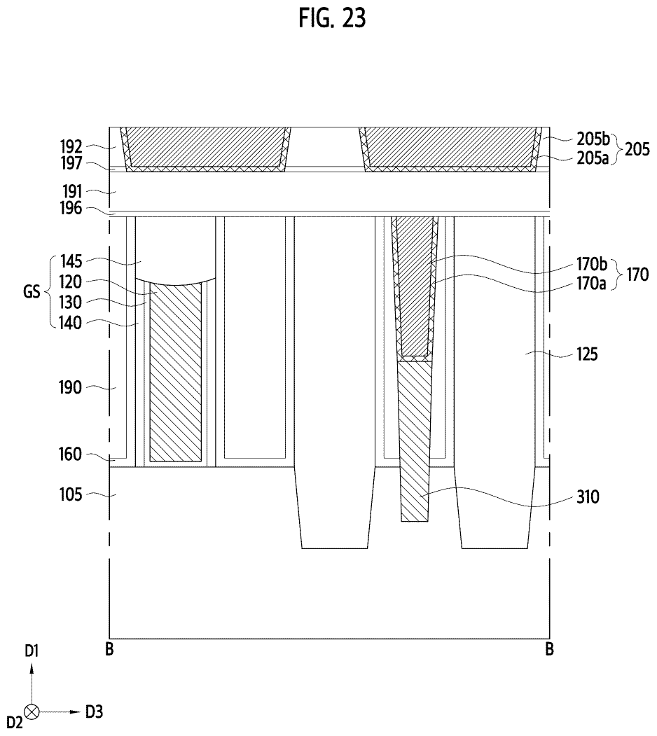

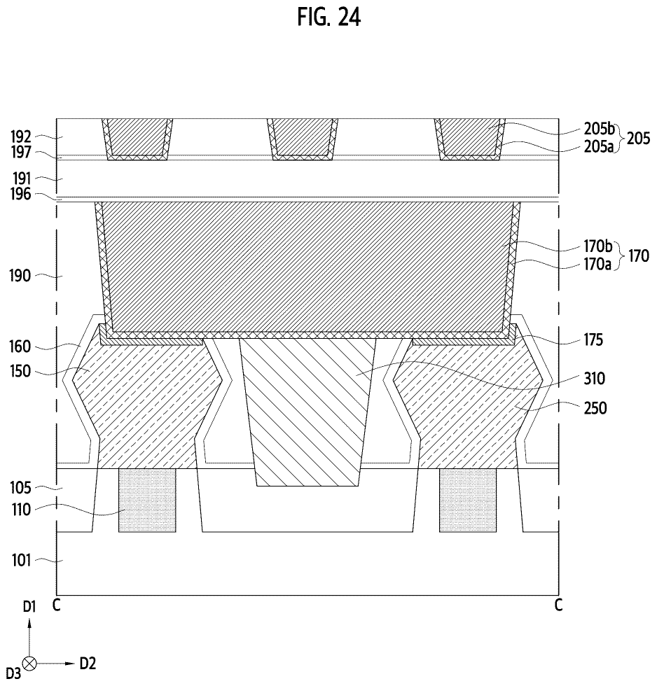

FIGS. 12 through 29 are diagrams illustrating an intermediate operation for describing a method of manufacturing a semiconductor device according to example embodiments. For reference, FIGS. 12 through 29 are diagrams illustrating the intermediate operation of the semiconductor device which is illustrated in FIGS. 2 through 5.

Referring to FIGS. 12 through 14, the supporter 110, the first source/drain pattern 150, and the second source/drain pattern 250 may be formed on a substrate 101. The first source/drain pattern 150 and the second source/drain pattern 250 may be formed on the supporter 110. The gate separation structure 125 may be formed on the field insulation film 105.

According to example embodiments, a pre-gate structure GSP may be formed after the first source/drain pattern 150 and the second source/drain pattern 250 are formed. The pre-gate structure GSP may be formed through a replacement metal gate (RMG) process.

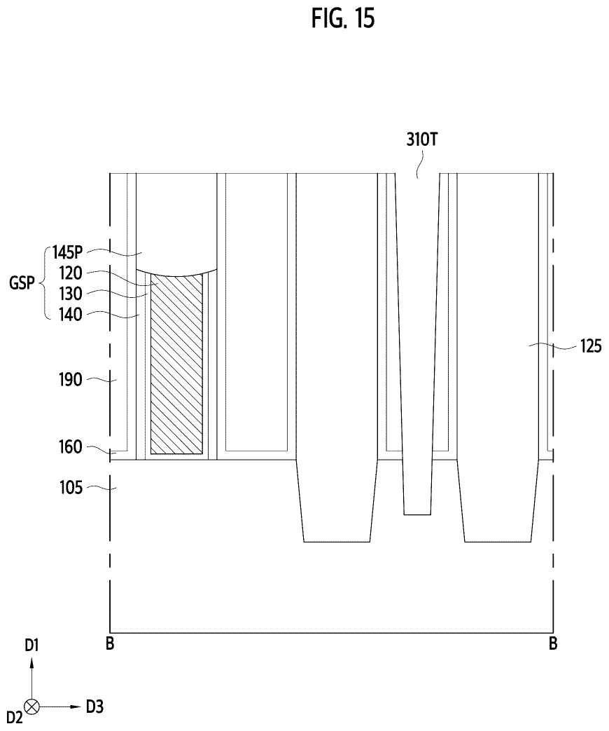

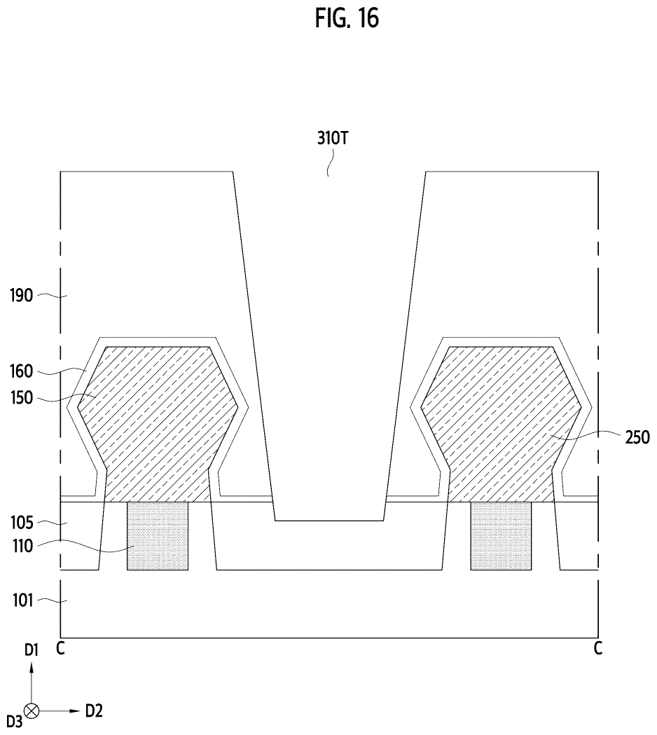

Referring to FIGS. 15 and 16, a backside connection via trench 310T penetrating at least a portion of the first frontside inter-layer insulation film 190 and the field insulation film 105 may be formed between gate separation structures 125 adjacent in the third direction.

According to example embodiments, the backside connection via trench 310T may be formed between the first source/drain pattern 150 and the second source/drain pattern 250 in the second direction D2.

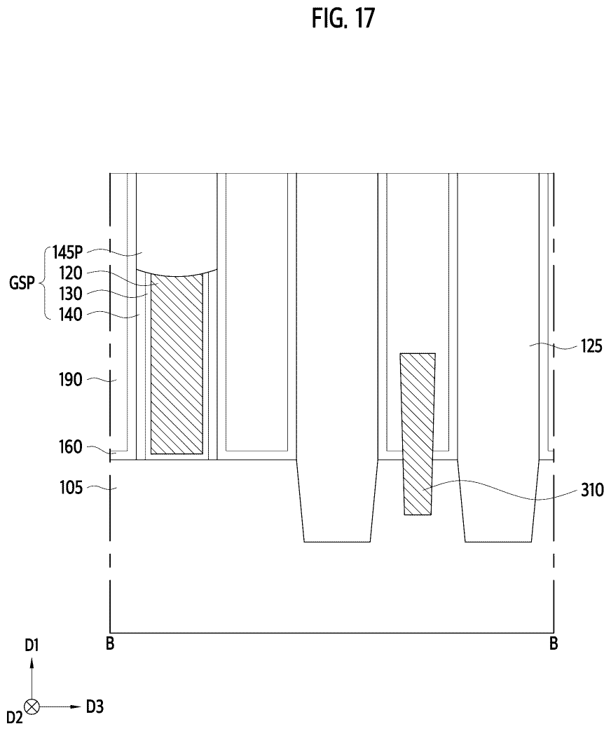

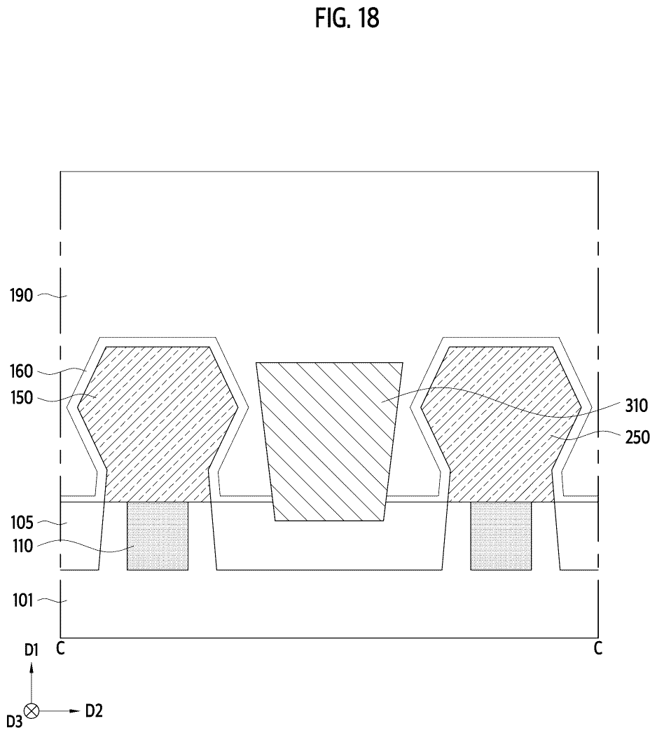

Referring to FIGS. 17 and 18, the backside connection via 310 may be formed in the backside connection via trench 310T (of FIGS. 15 and 16). An insulation film filling the backside connection via trench 310T (of FIGS. 15 and 16) may be formed on the backside connection via 310, so that the backside connection via 310 may be formed in the first frontside inter-layer insulation film 190.

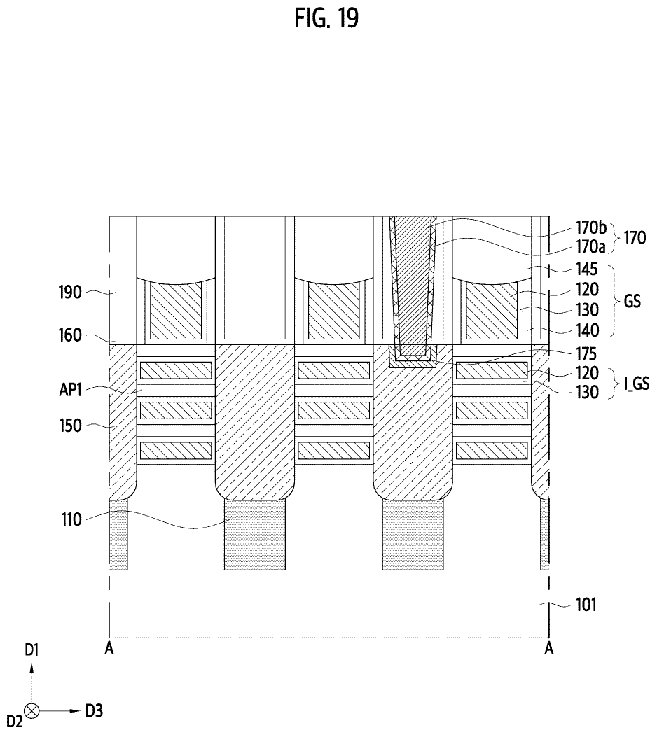

Referring to FIGS. 19 through 21, the first frontside source/drain contact 170 may be formed on the backside connection via 310. The first frontside source/drain contact 170 may be formed on the first source/drain pattern 150 and the second source/drain pattern 250. When the first frontside source/drain contact 170 is formed through a planarization process, a pre-gate capping film 145P of the pre-gate structure GSP is partially removed, so that the gate structure GS may be formed.

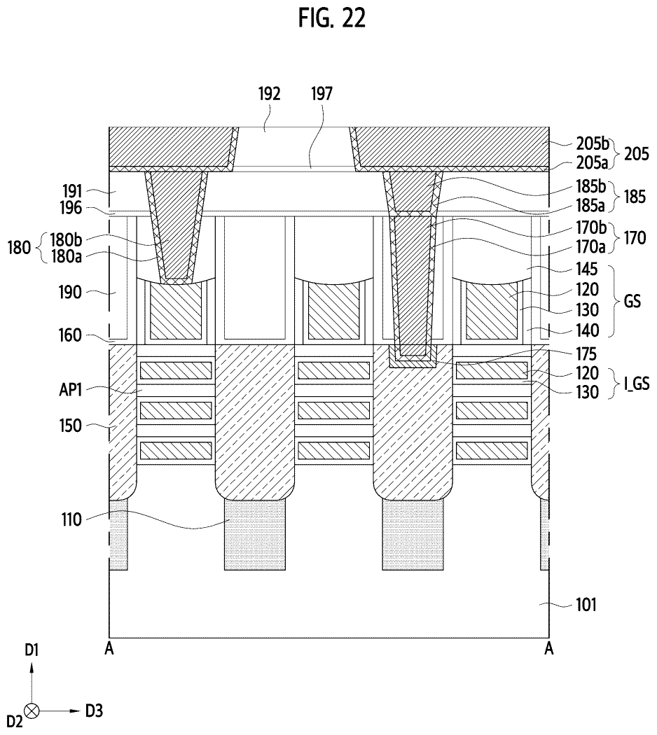

Referring to FIGS. 22 through 24, the first frontside etch stop film 196 and the second frontside inter-layer insulation film 191 may be formed on the first frontside inter-layer insulation film 190, the gate structure GS, and the first frontside source/drain contact 170. The frontside wiring via 185 which penetrates the first frontside etch stop film 196 and the second frontside inter-layer insulation film 191 may be formed, and the second frontside etch stop film 197 and the third frontside inter-layer insulation film 192 may be sequentially formed. Then, the second frontside etch stop film 197 and the third frontside inter-layer insulation film 192 may be formed, and the frontside wiring line 205 which is connected to the frontside wiring via 185 or the gate contact 180 may be formed.

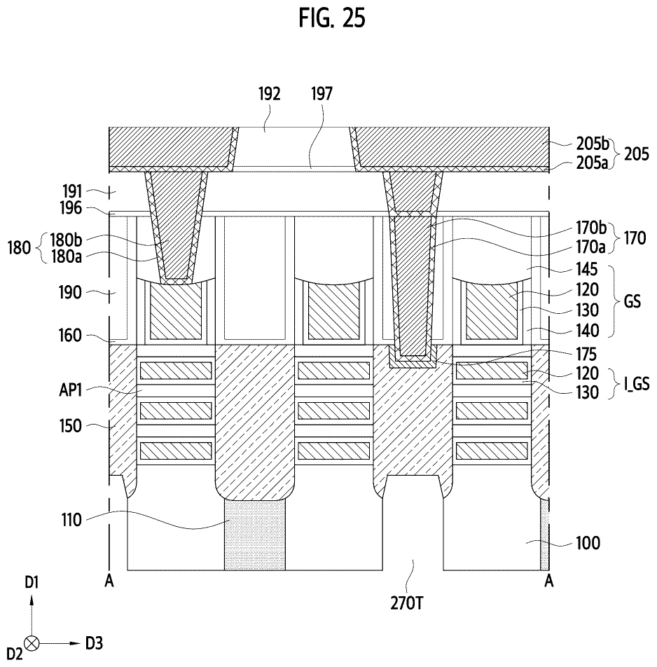

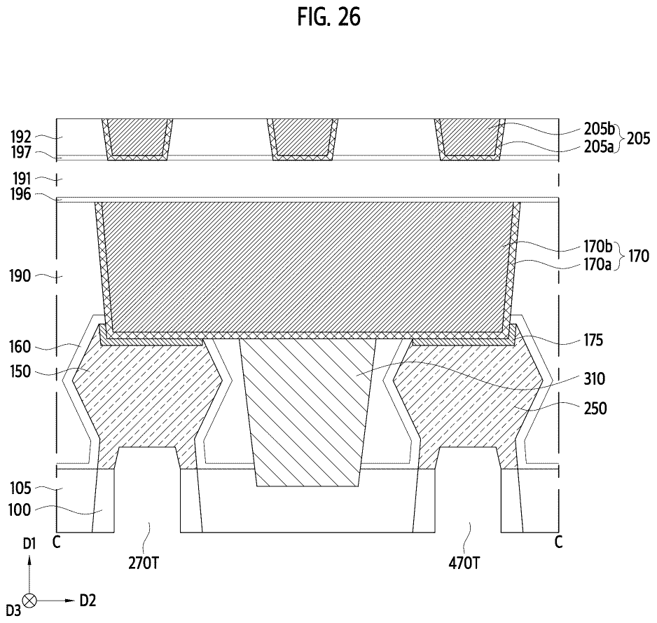

Referring to FIGS. 25 and 26, a portion of the substrate 101 (of FIGS. 22 through 24) may be removed from a backside of the substrate 101 (of FIGS. 22 through 24), so that the base pattern 100 may be formed. A portion of the supporter 110 may be removed, so that a first backside source/drain contact trench 270T and a second source/drain contact trench 470T that expose the first source/drain pattern 150 and the second source/drain pattern 250 may be formed. A portion of the first source/drain pattern 150 and the second source/drain pattern 250 which are exposed by removing the supporter 110 may be further removed, so that the first backside source/drain contact trench 270T and the second backside source/drain contact trench 470T may be formed.

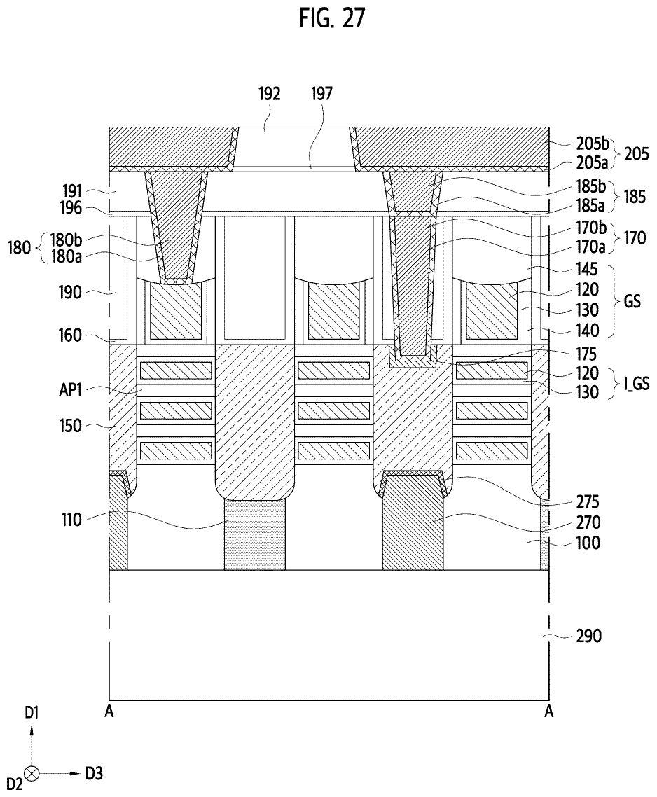

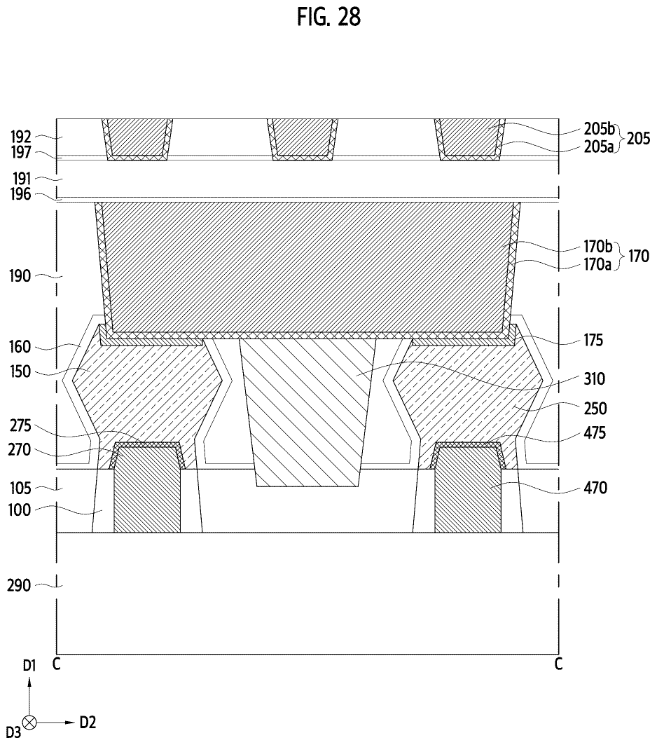

Referring to FIGS. 27 and 28, the first backside source/drain contact 270 and the second backside source/drain contact 470 may be formed in the first backside source/drain contact trench 270T (of FIGS. 25 and 26) and the second backside source/drain contact trench 470T (of FIGS. 25 and 26), respectively. The first backside inter-layer insulation film 290 may be formed below the base pattern 100, the first backside source/drain contact 270, and the second backside source/drain contact 470.

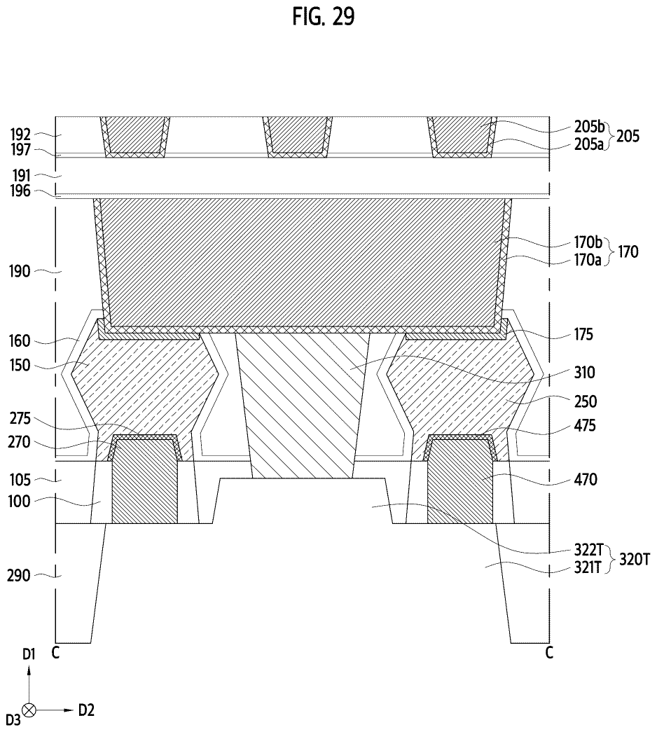

Referring to FIG. 29, a backside wiring pattern trench 320T penetrating the first backside inter-layer insulation film 290 may be formed. The backside connection via 310, the first backside source/drain contact 270, and the second backside source/drain contact 470 may be exposed through a backside wiring pattern trench 320T.

Then, referring to FIG. 4, the backside wiring pattern 320 may be formed in the backside wiring pattern trench 320T.

The various example embodiments of the present disclosure have been described above in detail, but the scope of the present disclosure is not necessarily limited thereto. It will be apparent to those skilled in the art that various changes and modifications may be allowed within the range of the technical spirit of the present disclosure. In addition, the above-described example embodiments may be implemented without a portion of elements thereof, and each of the example embodiments may be implemented in combination with another.

What is claimed is:

1. A semiconductor device, comprising:
a base pattern;
a first active pattern disposed on a frontside of the base pattern, the first active pattern being spaced apart from the base pattern in a first direction;
a second active pattern disposed on the frontside of the base pattern, the second active pattern being spaced apart from the base pattern in the first direction and being spaced apart from the first active pattern in a second direction crossing the first direction;
a first source/drain pattern connected to the first active pattern on the frontside of the base pattern;
a second source/drain pattern spaced apart from the first source/drain pattern in the second direction and connected to the second active pattern on the frontside of the base pattern;
a first backside source/drain contact connected to the first source/drain pattern from a backside of the base pattern disposed opposite to the frontside of the base pattern;
a backside wiring pattern disposed on the backside of the base pattern and extending in a third direction crossing the first direction and the second direction, the backside wiring pattern being connected to the first backside source/drain contact; and
a backside connection via disposed between the first source/drain pattern and the second source/drain pattern, extending in the first direction and connected to the backside wiring pattern.

2. The semiconductor device of claim 1, further comprising a first frontside source/drain contact connected to the first source/drain pattern on the frontside of the base pattern,
wherein the first frontside source/drain contact is connected to the backside connection via.

3. The semiconductor device of claim 2, wherein the first frontside source/drain contact is connected to the second source/drain pattern.

4. The semiconductor device of claim 1, further comprising a second backside source/drain contact connected to the second source/drain pattern from the backside of the base pattern,
wherein the backside wiring pattern is connected to the second backside source/drain contact.

5. The semiconductor device of claim 1, wherein the backside wiring pattern comprises:
a first portion connected to the first backside source/drain contact; and
a second portion that protrudes from the first portion in the first direction and is connected to the backside connection via.

6. The semiconductor device of claim 5, wherein a width of the second portion connected to the backside connection via is larger than a width of a backside of the backside connection via connected to the second portion.

7. The semiconductor device of claim 5, wherein, from the backside of the base pattern, a height of a frontside of the second portion is smaller than a height of a frontside of the base pattern.

8. The semiconductor device of claim 1, wherein, in the first direction, a backside of the backside connection via connected to the backside wiring pattern is closer to the backside of the base pattern than a backside of the first source/drain pattern connected to the base pattern.

9. The semiconductor device of claim 1, further comprising:
a gate electrode adjacent to the first source/drain pattern and the second source/drain pattern in the third direction and surrounding the first active pattern and the second active pattern; and
a gate separation structure disposed between the first active pattern and the second active pattern in the second direction and cutting the gate electrode.

10. The semiconductor device of claim 1, further comprising a first backside silicide film disposed between the first backside source/drain contact and the first source/drain pattern.

11. The semiconductor device of claim 1, wherein the backside wiring pattern overlaps the first active pattern and the second active pattern in the first direction.

12. The semiconductor device of claim 1, further comprising a source/drain etch stop film extended along the first source/drain pattern and the second source/drain pattern on the frontside of the base pattern,
wherein the backside connection via is surrounded by the source/drain etch stop film.

13. A semiconductor device, comprising:
a first active pattern comprising a plurality of first nano-sheets that are spaced apart from one another in a first direction;
a second active pattern, spaced apart from the first active pattern in a second direction crossing the first direction, and comprising a plurality of second nano-sheets that are spaced apart from one another in the first direction;
a first source/drain pattern connected to the first active pattern in a third direction crossing the first direction and the second direction;
a second source/drain pattern connected to the second active pattern in the third direction;
a first frontside source/drain contact disposed on the first source/drain pattern;
a first backside source/drain contact disposed below the first source/drain pattern; and
a backside connection via disposed between the first source/drain pattern and the second source/drain pattern, extended in the first direction, and connected to the first frontside source/drain contact.

14. The semiconductor device of claim 13, further comprising a backside wiring pattern that is disposed below the first source/drain pattern and the second source/drain pattern, is extended in the third direction, and is connected to the first backside source/drain contact and the backside connection via.

15. The semiconductor device of claim 14, wherein, in the second direction, a width of the backside wiring pattern is larger than a distance between the first active pattern and the second active pattern.

16. The semiconductor device of claim 14, wherein, based on the first frontside source/drain contact, a first frontside on which the backside wiring pattern is connected to the first backside source/drain contact is disposed below a second frontside on which the backside wiring pattern is connected to the backside connection via.

17. The semiconductor device of claim 14, further comprising a second backside source/drain contact disposed below the second source/drain pattern,
wherein the first frontside source/drain contact is connected to the second source/drain pattern, and
wherein the second backside source/drain contact is connected to the backside wiring pattern.

18. The semiconductor device of claim 13, further comprising:
a first frontside silicide film disposed between the first frontside source/drain contact and the first source/drain pattern; and
a first backside silicide film disposed between the first backside source/drain contact and the first source/drain pattern.

19. The semiconductor device of claim 13, further comprising:
a source/drain etch stop film extended along the first source/drain pattern and the second source/drain pattern; and
a first frontside inter-layer insulation film disposed on the source/drain etch stop film,
wherein the backside connection via penetrates the first frontside inter-layer insulation film.

20. A semiconductor device, comprising:
a first active pattern comprising a plurality of first nano-sheets that are spaced apart from one another in a first direction;
a second active pattern spaced apart from the first active pattern in a second direction crossing the first direction and comprising a plurality of second nano-sheets that are spaced apart from one another in the first direction;
a first source/drain pattern connected to the first active pattern in a third direction crossing the first direction and the second direction;
a second source/drain pattern connected to the second active pattern in the third direction;
a first frontside source/drain contact disposed on the first source/drain pattern and the second source/drain pattern;
a first backside source/drain contact disposed below the first source/drain pattern;
a second backside source/drain contact disposed below the second source/drain pattern;
a backside connection via disposed between the first source/drain pattern and the second source/drain pattern, extending in the first direction, and connected to the first frontside source/drain contact; and
a backside wiring pattern disposed below the first source/drain pattern and the second source/drain pattern, extending in the third direction, and is connected to the first backside source/drain contact, the second backside source/drain contact, and the backside connection via.
